(19) United States
(12) Patent Application Publication
(10) Pub. No.: US 2015/0226776 A1
(43) Pub. Date: Aug. 13, 2015

(54) METHOD AND DEVICE FOR MEASURING INDUCTANCE OF PERMANENT MAGNET SYNCHRONOUS MOTOR, AND PERMANENT MAGNET SYNCHRONOUS MOTOR

(71) Applicant: NIDEC CORPORATION, Minami-ku, Kyoto (JP)

(72) Inventors: Tokoh Nishikubo, Kyoto (JP); Kazumasa Ue, Kyoto (JP)

(21) Appl. No.: 14/404,681

(22) PCT Filed: Sep. 24, 2013
(86) PCT No.: PCT/JP2013/075658

§ 371 Date: Dec. 1, 2014

Related U.S. Application Data
(60) Provisional application No. 61/705,269, filed on Sep. 25, 2012.

(51) Int. Cl. G01R 27/26; H02P 21/13; H02P 21/14

(52) U.S. Cl. CPC G01R 27/2611; H02P 21/14; H02P 21/13

(57) ABSTRACT

A method for measuring an inductance of a permanent magnet synchronous motor includes the steps of applying to a stator of a stationary portion of the permanent magnet synchronous motor a measuring voltage having an electric angular velocity at which a rotary portion is not rotated, in parallel with the previous step, measuring a response current flowing through the stator by using a static phase of the rotary portion that is kept stopped with respect to the stationary portion, determining a differential value of the response current by using a digital filter, and obtaining an inductance of the stator by inputting the response current and the differential value of the response current to a converter prepared in advance.

### BACKGROUND OF THE INVENTION

1. Field of the Invention

The present invention relates to a technology for measuring an inductance of a permanent magnet synchronous motor.

2. Description of the Related Art

Recently, in view of reducing an environmental load and tightening power supply ability, an energy saving technology is desired in many different fields. In particular, high efficiency is required in motors that account for about 50% of the electric power consumed in Japan. A permanent magnet synchronous motor (hereinafter referred to as “PMSM”) can realize high efficiency, wide range drive, high output density and high torque. For that reason, the PMSM is utilized in many household and industrial fields. Control technologies used in the PMSM diverges into many branches. Among the control technologies, a vector control simultaneously satisfies high torque, low vibration, and high efficiency against load variations in the PMSM. Thus, the vector control constitutes a core of the control technologies of the PMSM. Except a special case in which a highly accurate positioning is required, the vector control is currently required to not have a position sensor in view of reducing the costs and enhancing the reliability. For the very reason, it can be said that the vector control will be further developed in the future.

In the position-sensorless vector control, it is widely known that an error of an inductance of the PMSM, particularly an error of a q-axis inductance, heavily affects a phase estimating characteristic. Recently, there is also proposed a trajectory-oriented sensorless vector control method. In the trajectory-oriented sensorless vector control method, an inductance in a phase estimating observer is caused to have an intentional error, thereby generating a phase estimation error and shifting a current phase toward an MTPA (Maximum Torque Per Ampere) curve. An inductance value of the PMSM used in this control method is measured by an LCR meter, an impedance method, a magnetic flux linkage method or the like. The inductance value of the PMSM is often provided as a nominal value from different makers.

In the method using the LCR meter, a measured current is smaller than a rated current. Further, in a rated operation, an influence of magnetic saturation or the like needs to be taken into account. For that reason, the measured inductance value in the method using the LCR meter is not enough to be used as a true value in the rated operation. In the method using the LCR meter, data corresponding to one cycle of an electric angle is needed. The impedance method is implemented with respect to the PMSM kept in a stop state. In the impedance method, it is easy to measure a d-axis inductance which does not accompany any torque generation. However, in the impedance method, an external load device for fixing a rotor with a force larger than a generated torque is required in order to measure a q-axis inductance. In the magnetic flux linkage method, an inductance is calculated based on a voltage equation in the rated rotation of the PMSM. Therefore, as in the impedance method, an external load device is required in the magnetic flux linkage method. All the methods mentioned above require a position sensor in order to obtain a rotor phase. In all the aforementioned methods, at least one hour is required for the measurement including the setup of the position sensor.

A measurement result or a simulation result of a prototype motor is often used as a nominal value of an inductance of the PMSM. Even at a rated load point, the nominal value of the inductance includes a manufacturing error between the prototype motor and an actually-used motor. Since measurement conditions differ in the prototype motor and the actually-used motor, the inductance nominal value includes an error with respect to the points other than the rated load point. That is to say, in the position-sensorless vector control, the use of the inductance nominal value generates a phase estimation error.

Meanwhile, there are also proposed many other methods for measuring an inductance. For example, in the second preferred embodiment of Japanese Patent Application Publication No. H9-285198, a difference between a d-axis inductance estimation value L_{d}*** and a q-axis inductance estimation value L_{q}*** is found from an output signal when the motor revolution number is 0. The difference thus found is used in correcting a torque. In that embodiment, the respective values of a d-axis inductance and a q-axis inductance are not required. Japanese Patent Application Publication No. 2000-50700 discloses a method for finding a d-axis inductance L_{d} by applying a voltage in which an alternating current overlaps with a direct current in a d-axis direction and for finding a q-axis inductance L_{q} by applying an alternating current which vibrates in a q-axis direction.

In the method disclosed in Japanese Patent Application Publication No. H9-285198, it is not possible to individually find a d-axis inductance and a q-axis inductance. In the technology disclosed in Japanese Patent Application Publication No. 2000-50700, the measurement work needs to be performed twice, and is time-consuming.

Further, in the technology disclosed in Japanese Patent Application Publication No. 2000-50700, the current flowing through a stator coil increases. For that reason, magnetic saturation is easily generated and thus the measurement accuracy is reduced. In that technology, the voltage in which an alternating current overlaps with a direct current significantly differs from a voltage at the driving time. Therefore, it may not be possible to obtain a desirable inductance. In addition, when measuring a coil resistance, it is usually required to apply a low drive voltage to the PMSM kept in a stop state. This leads to a reduction in accuracy. Thus, in the technology disclosed in Japanese Patent Application Publication No. 2000-50700 where a nominal value is not used as a coil resistance, there is a fear that it may be impossible to obtain a coil resistance with high accuracy.

### SUMMARY OF THE INVENTION

Preferred embodiments of the present invention make it possible to, e.g., easily measure an inductance within a short period of time.

A method for measuring an inductance of a permanent magnet synchronous motor according to one illustrative preferred embodiment of the present invention includes the steps of: (a) applying, to a stator of a stationary portion of the permanent magnet synchronous motor, a measuring voltage having an electric angular velocity at which a rotary portion is not rotated; (b) in parallel with the step (a), measuring a response current flowing through the stator by using a static phase of the rotary portion that is kept stopped with respect to the stationary portion; (c) finding a differential value of the response current by using a digital filter; and (d) obtaining an inductance of the stator by inputting the response current and the differential value of the response current to a converter prepared in advance.

One illustrative preferred embodiment of the present invention can be utilized in, e.g., a device for measuring an inductance of a permanent magnet synchronous motor, and a permanent magnet synchronous motor.

According to one illustrative preferred embodiment of the present invention, it is possible to easily measure an inductance within a short period of time.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a view showing a configuration in accordance with a preferred embodiment of the present invention in which a response current is converted by a mapping filter.

FIG. 2A is a view illustrating a gain characteristic of a mapping filter in accordance with a preferred embodiment of the present invention.

FIG. 2B is a view illustrating a phase characteristic of a mapping filter in accordance with a preferred embodiment of the present invention.

FIG. 3A is a view showing a measurement flow of an inductance in accordance with a preferred embodiment of the present invention.

FIG. 3B is a view showing schematic configurations of a PMSM and an inductance measuring device in accordance with a preferred embodiment of the present invention.

FIG. 4A is a view showing a measuring voltage and a response current in accordance with a preferred embodiment of the present invention.

FIG. 4B is a view showing a measuring voltage and a response current in accordance with a preferred embodiment of the present invention.

FIG. 5 is a view showing a generated torque, a rotor phase, and a rotor electric velocity in accordance with a preferred embodiment of the present invention.

FIG. 6 is a view illustrating an inductance measurement result in accordance with a preferred embodiment of the present invention.

FIG. 7 is a view showing a mask in accordance with a preferred embodiment of the present invention.

FIG. 8 is a view illustrating an inductance measurement result in accordance with a preferred embodiment of the present invention after masking.

FIG. 9A is a view illustrating an inductance measurement result in accordance with a preferred embodiment of the present invention when a frequency is changed.

FIG. 9B is a view illustrating an inductance measurement result in accordance with a preferred embodiment of the present invention when a frequency is changed.

FIG. 10 is a view showing a measuring voltage and a response current in accordance with a preferred embodiment of the present invention.

FIG. 11 is a view illustrating an inductance measurement result in accordance with a preferred embodiment of the present invention.

FIG. 12 is a view showing a measuring voltage and a response current in accordance with a preferred embodiment of the present invention.

FIG. 13 is a view illustrating an inductance measurement result in accordance with a preferred embodiment of the present invention.

FIG. 14 is a view showing an improved measuring-voltage applying unit, a current measuring unit, and an inductance calculating unit in accordance with a preferred embodiment of the present invention.

FIG. 15A is a view showing a target current in accordance with a preferred embodiment of the present invention.

FIG. 15B is a view showing a target current generating unit in accordance with a preferred embodiment of the present invention.

FIG. 15C is a view showing a response current converting unit in accordance with a preferred embodiment of the present invention.

FIG. 15D is a view showing a measuring-voltage generating unit in accordance with a preferred embodiment of the present invention.

FIG. 16 is a view showing an initial phase in accordance with a preferred embodiment of the present invention.

FIG. 17A is a view showing a measuring voltage and a response current in accordance with a preferred embodiment of the present invention.

FIG. 17B is a view illustrating an inductance measurement result in accordance with a preferred embodiment of the present invention.

### DETAILED DESCRIPTION OF THE PREFERRED EMBODIMENTS

In the following description, if a superscript “B” is affixed to a right upper portion of a symbol, the symbol indicates a vector or a matrix. In mathematical formulae, if a symbol is expressed as a bold letter, the symbol indicates a vector or a matrix.

In an inductance measuring method according to the present preferred embodiment of the present invention (hereinafter referred to as “present measuring method”), for example, a dynamic mathematical model for a PMSM expressed in mathematical formula 1 is used. The dynamic mathematical model is built on a γ-δ general coordinate system pursuant to Shinji Shinnaka, “Vector Control Technology of Permanent Magnet Synchronous Motor, First Volume (from the Principle to the Forefront)”, Dempa Publications Inc., December 2008.

$${v}_{1} = {R}_{1} {i}_{1} + D ( s , {ω}_{γ} ) {φ}_{1} \\ {φ}_{1} = {φ}_{i} + {φ}_{m} \\ {φ}_{i} = [ {L}_{i} I + {L}_{m} Q ( {θ}_{γ} ) ] {i}_{1} \\ {φ}_{m} = Φ [ \begin{matrix}cos {θ}_{γ} \\ sin {θ}_{γ}\end{matrix} ] \\ s {θ}_{γ} = {ω}_{2 n} - {ω}_{γ} \\ {ω}_{2 n} = {N}_{p} {ω}_{2 m} \\ τ = {N}_{p} {i}_{1}^{T} J {φ}_{1} \\ {ω}_{2 m} = \frac{τ}{{J}_{m} s + {D}_{m}} \\ D ( s , {ω}_{γ} ) = sI + {ω}_{γ} J \\ Q ( {θ}_{γ} ) = [ \begin{matrix}cos 2 {θ}_{γ} & sin 2 {θ}_{γ} \\ sin 2 {θ}_{γ} & - cos 2 {θ}_{γ}\end{matrix} ] \\ I = [ \begin{matrix}1 & 0 \\ 0 & 1\end{matrix} ] , J = [ \begin{matrix}0 & - 1 \\ 1 & 0\end{matrix} ] \qquad Mathematical Formula 1$$

In mathematical formula 1, s denotes a differential operator. T as a superscript means transposition of a matrix. ω_{γ} is a rotational velocity of a coordinate system in which a direction extending from the γ-axis to the δ-axis is positive. ω₂ₙ is an instantaneous velocity of a rotor. θ_{γ} is an instantaneous phase of an N-pole of the rotor evaluated from the γ-axis. 2×2 vectors D^{B}(s, ω_{γ}), Q^{B}(θ_{γ}), I^{B} and J^{B} are a D factor (D-matrix), a mirror matrix, a unit matrix and an alternating matrix, respectively. 2×1 vectors v^{B}₁, i^{B}₁ and cφ^{B}₁ are a voltage, current, and magnetic flux linkage of the rotor, respectively. φ^{B}ᵢ is an armature reaction magnetic flux (a stator reaction magnetic flux) and is generated by a stator current i^{B}₁. φ^{B}ₘ is a rotor magnetic flux linking with a stator coil. The stator magnetic flux linkage φ^{B}₁ is the sum of the armature reaction magnetic flux φ^{B}ᵢ and the rotor magnetic flux φ^{B}ₘ. R₁ is a coil resistance of the PMSM. τ is a generated torque of the PMSM. Jₘ is an inertia moment of the PMSM. Dₘ is a viscous friction of the PMSM. ω₂ₘ is a mechanical velocity and is a value obtained by dividing the instantaneous velocity ω₂ₙ of the rotor by a pole pair number Nₚ. Lᵢ and Lₘ are an in-phase inductance and a mirror phase inductance, respectively. Each of the in-phase inductance Lᵢ and the mirror phase inductance Lₘ includes a mutual inductance between u, v and w phases. The in-phase inductance Lᵢ and the mirror phase inductance Lₘ are related with a d-axis inductance L_{d} and a q-axis inductance L_{q} as expressed in mathematical formula 2.

$$[ \begin{matrix}{L}_{d} \\ {L}_{q}\end{matrix} ] = [ \begin{matrix}1 & 1 \\ 1 & - 1\end{matrix} ] [ \begin{matrix}{L}_{i} \\ {L}_{m}\end{matrix} ] \qquad Mathematical Formula 2$$

The conditions of this mathematical model are as follows.

(1) Electric and magnetic characteristics of u, v and w phases are identical.

(2) Harmonic wave components of a current and a magnetic flux are negligible.

(3) A permanent magnet of the rotor of the PMSM is magnetized with a sinusoidal wave.

(4) An influence of magnetic flux interference between axes is negligible.

(5) An iron loss as a magnetic circuit loss is negligible.

Now, consideration is given to a case where a measuring voltage v^{B}₁ₕ expressed in mathematical formula 3 is represented on a γ-δ general coordinate system. In mathematical formula 3, vₕ and ωₕ are the amplitude and the angular frequency of the measuring voltage.

$${v}_{1 h} = {V}_{h} [ \begin{matrix}cos {ω}_{h} t \\ sin {ω}_{h} t\end{matrix} ] \qquad Mathematical Formula 3$$

A generated response current i^{B}₁ₕ is expressed by mathematical formula 4 using a phase Δθ. The phase Δθ is based on the measuring voltage v^{B}₁ₕ. In mathematical formula 4, i_{hγ} and i_{hδ} are current amplitudes of γ-axis and δ-axis components, respectively.

$${i}_{1 h} = [ \begin{matrix}{i}_{h γ} cos & ( {ω}_{h} t + Δ θ ) \\ {i}_{h δ} sin & ( {ω}_{h} t + Δ θ )\end{matrix} ] \\ {i}_{h γ} , {i}_{h δ} ∝ {V}_{h} \qquad Mathematical Formula 4$$

In the present measuring method, an inductance of the PMSM is measured by applying the measuring voltage expressed in mathematical formula 3 to the PMSM. Under a condition that the angular frequency ωₕ of the applied measuring voltage is sufficiently higher than a mechanical system time constant Dₘ/Jₘ (e.g., ten times as high as the mechanical system time constant Dₘ/Jₘ), the generated torque becomes a rotor holding force. As a result, the rotor electric velocity ω₂ₙ of mathematical formula 1 becomes 0, such that mathematical formula 5 is established.

$${v}_{1 h} = {R}_{1} {i}_{1 h} + [ sI + {ω}_{γ} J ] ( [ {L}_{i} I + {L}_{m} Q ( {θ}_{γ} ) ] {i}_{1 h} + Φ [ \begin{matrix}cos θγ \\ sin {θ}_{γ}\end{matrix} ] ) \\ s {θ}_{γ} = - {ω}_{γ} \qquad Mathematical Formula 5$$

Mathematical formula 5 can be rearranged into mathematical formula 6.

LᵢI[si₁ₕ+ω_{γ}JiL₁ₕ]+LₘQ(θ_{γ})[si₁ₕ+ω_{γ}Ji₁ₕ]=v₁ₕ−R₁i₁ₕ Mathematical Formula 6

As for the si^{B}₁ₕ of mathematical formula 6, the relationship of mathematical formula 7 can be obtained from mathematical formula 4. That is to say, the si^{B}₁ₕ can be obtained by advancing the phase of a current i^{B}₁ₕ by π/2 rad and causing the ωₕ to act as a gain.

$$\begin{matrix}{si}_{1 h} = [ \begin{matrix}- {i}_{h γ} {ω}_{h} sin & ( {ω}_{h} t + Δ θ ) \\ {i}_{h δ} {ω}_{h} cos & ( {ω}_{h} t + Δ θ )\end{matrix} ] \\ = {ω}_{h} [ \begin{matrix}{i}_{h γ} cos & ( {ω}_{h} t + Δ θ + π \text{/} 2 ) \\ {i}_{h δ} sin & ( {ω}_{h} t + Δ θ + π \text{/} 2 )\end{matrix} ]\end{matrix} \qquad Mathematical Formula 7$$

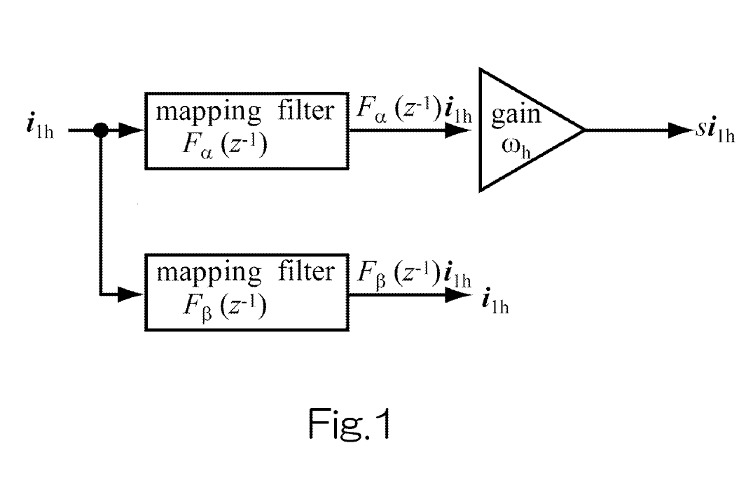

Accordingly, in the present measuring method, mapping filters are used to obtain the si^{B}₁ₕ. FIG. 1 is a view showing a schematic configuration in which the i^{B}₁ₕ is converted by mapping filters F_{α}(z⁻¹) and F_{β}(z⁻¹). In the case where the control cycle Tₛ is 0.1 ms and the angular frequency ωₕ of the measuring voltage is 800π rad/s, the mapping filters F_{α}(z⁻¹) and F_{β}(z⁻¹) are digital filters expressed in mathematical formula 8. Δθₕ is a normalized angular frequency, k is an integer, n is a degree of the filters, and r is a parameter used in realizing recursion of the filters.

$${F}_{α} ( {z}^{- 1} ) = \frac{2}{n} \frac{- r sin Δ {θ}_{h} {z}^{- 1} \{ 1 - {( - 1 )}^{k} {r}^{n} {z}^{- n} \}}{1 - 2 r cos Δ {θ}_{h} {z}^{- 1} + {r}^{2} {z}^{- 2}} \\ {F}_{β} ( {z}^{- 1} ) = \frac{2}{n} \frac{( 1 - r cos Δ {θ}_{h} {z}^{- 1} ) \{ 1 - {( - 1 )}^{k} {r}^{n} {z}^{- n} \}}{1 - 2 r cos Δ {θ}_{h} {z}^{- 1} + {r}^{2} {z}^{- 2}} \\ r = 0.9999 , k = 2 \\ Δ {θ}_{h} = {T}_{s} {ω}_{h} = 0.08 π \\ n = \frac{k π}{Δ {θ}_{h}} = 25 \qquad Mathematical Formula 8$$

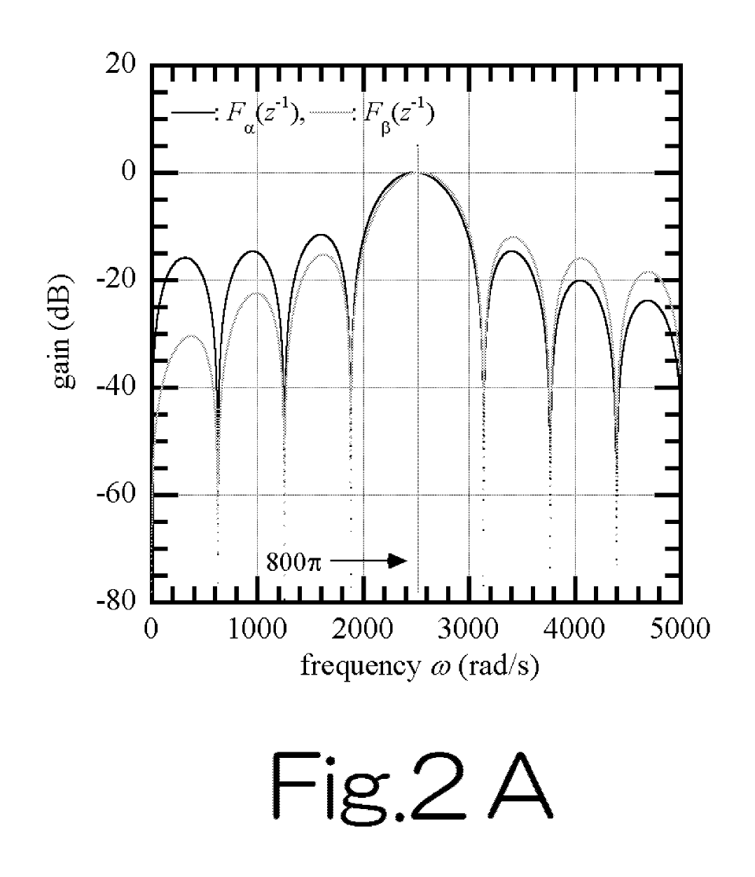

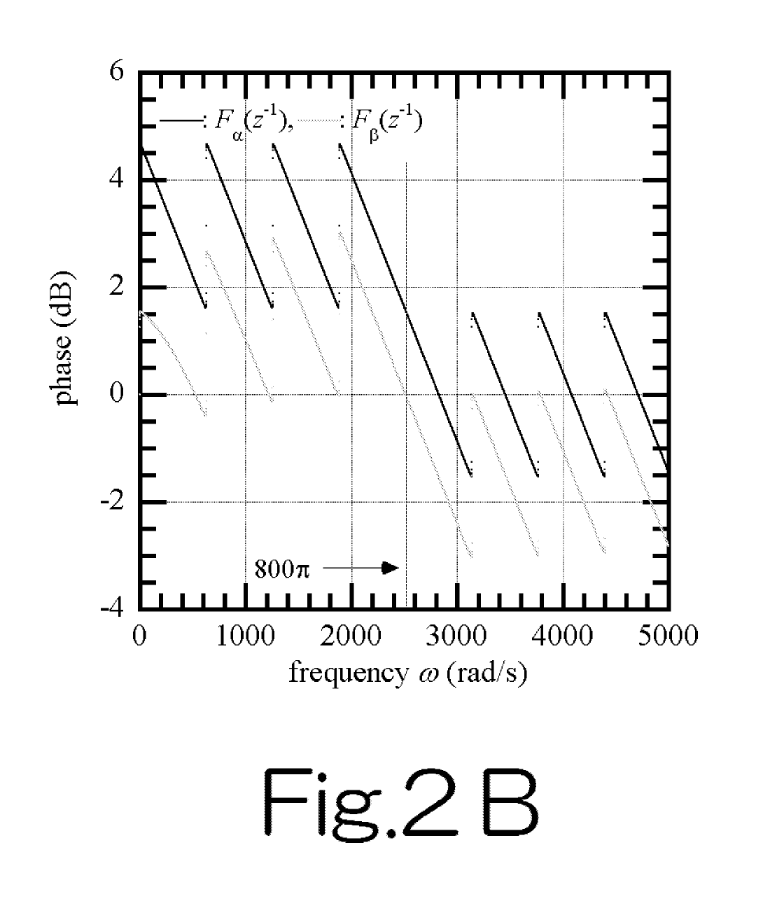

FIGS. 2A and 2B show the angular frequency characteristics of the mapping filters of mathematical formula 8 when a sampling frequency is 10 kHz. FIG. 2A shows a gain characteristic and FIG. 2B shows a phase characteristic. The black line indicates the characteristic of the mapping filter F_{α}(z⁻¹) and the gray line indicates the characteristic of the mapping filter F_{β}(z⁻¹). The mapping filter F_{α}(z⁻¹) makes the phase of the i^{B}₁ₕ having the angular frequency ωₕ of 800π rad/s advance by π/2 rad. On the other hand, the mapping filter F_{β}(z⁻¹) makes the frequency component of the ωₕ pass therethrough without changing the phase of the i^{B}₁ₕ. Thus, the S/N ratio of the response current i^{B}₁ₕ is improved. Then, the Lᵢ and the Lₘ are found by substituting the v^{B}₁ₕ, the i^{B}₁ₕ and the si^{B}₁ₕ obtained from mathematical formulae 3, 4, and 7 into mathematical formula 6.

A d-q fixed coordinate system is a fixed d-q coordinate system in which θ_{γ}=0 and ω_{γ}=ω₂ₙ=0. The d-q fixed coordinate system can be regarded as a special case of the γ-δ general coordinate system. In the d-q fixed coordinate system, mathematical formula 6 can be simplified as expressed in mathematical formula 9. For instance, a nominal value is used as the coil resistance R₁.

$$[ \begin{matrix}{L}_{d} \\ {L}_{q}\end{matrix} ] = [ \begin{matrix}\frac{{v}_{d} - {R}_{1} {i}_{d}}{{si}_{d}} \\ \frac{{v}_{q} - {R}_{1} {i}_{q}}{{si}_{q}}\end{matrix} ] \qquad Mathematical Formula 9$$

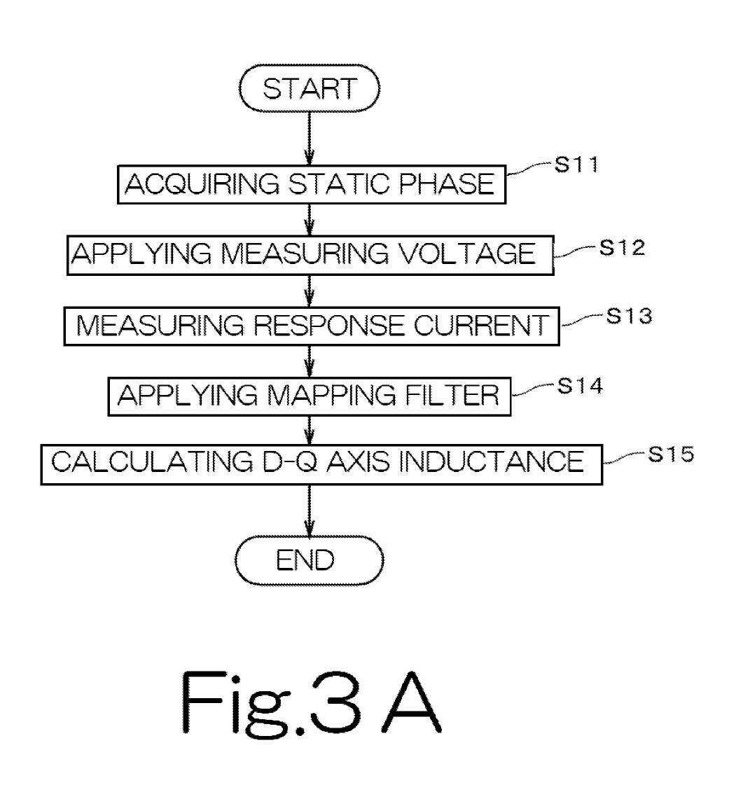

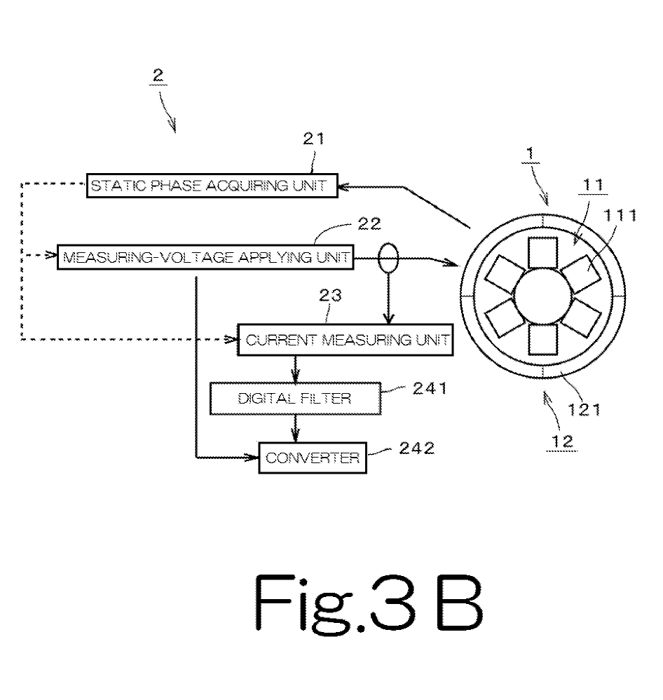

FIG. 3A is a view showing a measurement flow of the inductance of the PMSM. FIG. 3B is a view showing schematic configurations of the PMSM 1 and an inductance measuring device 2. The inductance measuring device 2 may be installed within the PMSM 1. In this case, the respective components of the inductance measuring device 2 to be described hereinafter are preferably included in a control unit installed on a circuit board of the PMSM 1. The PMSM 1 includes a stationary portion 11 and a rotary portion (a rotor) 12. The stationary portion 11 includes a stator 111. The rotary portion 12 includes a permanent magnet 121. The stationary portion 11 supports the rotary portion 12 such that the rotary portion 12 is rotatable.

The inductance measuring device 2 preferably includes a static phase acquiring unit 21, a measuring-voltage applying unit 22, a current measuring unit 23, a digital filter 241m and a converter 242. The static phase acquiring unit 21 acquires a static phase (namely, a rotational position in a stop state) of the rotary portion 12 which is stopped with respect to the stationary portion 11 of the PMSM 1. The static phase is given to the measuring-voltage applying unit 22 and the current measuring unit 23, in which the static phase is used in the coordinate conversion of a voltage and a current.

The measuring-voltage applying unit 22 is configured to apply a measuring voltage to the stator 111. As will be described later, the measuring voltage includes an electric angular velocity at which the rotary portion 12 is not substantially rotated. The current measuring unit 23 is configured to measure a response current flowing through the stator 111 to which the measuring voltage is applied. The digital filter 241 preferably includes the configuration shown in FIG. 1. The digital filter 241 finds a differential value of the response current or performs noise removal. The converter 242 is configured to convert the response current, the measuring voltage, and the differential value of the response current to an inductance of the stator 111. If the measuring voltage is predetermined, the converter 242 actually converts the response current and the differential value of the response current to an inductance.

FIG. 3B merely illustrates a functional configuration of the inductance measuring device 2. Practically, the static phase acquiring unit 21 is preferably realized by an inverter of the PMSM 1 and a control circuit thereof. The current measuring unit 23 is preferably realized by, for example, a calculating unit and the like. The measuring-voltage applying unit 22 is preferably realized by, for example, an inverter, a control circuit, a calculating unit, and the like. The digital filter 241 or the converter 242 is also preferably realized by, for example, a calculating unit and the like. However, there is no need to provide these components to be distinguished physically.

As shown in FIG. 3A, when measuring the inductance, the static phase acquiring unit 21 initially acquires the static phase θ_{α} of the rotary portion 12, which is stopped with respect to the stationary portion 11, by a static phase estimation method using magnetic saturation (step S11). As the static phase estimation method, it is possible to use a method which is recited in Shinji Shinnaka, “Vector Control Technology of Permanent Magnet Synchronous Motor, Second Volume (Essence of Sensorless Drive Control)”, Dempa Publications Inc., December 2008. Other arbitrary methods may be used as the static phase estimation method if so desired. The static phase estimation method is not limited to calculation. If the PMSM 1 includes a position sensor, the static phase may be acquired using the position sensor. Moreover, the static phase may be predetermined.

Next, the measuring-voltage applying unit 22 applies the measuring voltage v^{B}₁ₕ expressed in mathematical formula 3 to the stator 111 (step S12). The measuring voltage has an electric angular velocity at which the rotary portion 12 is not rotated. In parallel with step S12, the current measuring unit 23 measures the response current i^{B}₁ₕ flowing through the stator 111 to which the measuring voltage is applied (step S13). More specifically, in the measuring-voltage applying unit 22, a predetermined measuring voltage is converted from a d-q fixed coordinate system to an α-β coordinate system through the use of the static phase θ_{α} and is converted from two phases to three phases. Thus, the control of an inverter is implemented. In the current measuring unit 23, the current flowing through the stator 111 is converted from three phases to two phases and is converted from an α-β coordinate system to a d-q fixed coordinate system through the use of the static phase θ_{α}. Consequently, a d-axis current and a q-axis current are acquired as the response current.

Due to the use of the digital filter 241, the mapping filter F_{α}(z⁻¹) of mathematical formula 8 is applied to the i^{B}₁ₕ. Accordingly, the si^{B}₁ₕ is obtained by advancing the differential value of the response current, i.e., the phase of the response current by π/2 rad (step S14). In the digital filter 241, the i^{B}₁ₕ with a reduced noise can also be obtained when the mapping filter F_{β}(z⁻¹) is applied. In the converter 242, a d-axis inductance L_{d} and a q-axis inductance L_{q} are calculated by substituting the respective variable values into mathematical formula 9 (step S15).

Practically, during one cycle of the response current, a plurality of d-axis current values is acquired and a plurality of q-axis current values corresponding to the d-axis current values is acquired. For that reason, in step S15, a plurality of d-axis inductance values corresponding to the d-axis current values and a plurality of q-axis inductance values corresponding to the q-axis current values are acquired as the inductance. In this manner, the inductance values corresponding to the current values are rapidly acquired. Preferably, the converter 242 includes, for example, a function or a table for converting the response current and the differential value of the response current to inductances. In other words, the converter 242 may be a calculating unit that finds inductances using a function or may be configured to find inductances by referring to a table. Accordingly, it is possible to acquire a plurality of inductances at a high speed.

The inductances thus found are used in, e.g., adjusting the drive control of PMSMs during the manufacture thereof or performing a quality assurance inspection.

The aforementioned inductance measurement is based on a premise that the rotary portion 12 is not moved even if the measuring voltage is applied to the stator 111. Thus, first of all, description will be made on the result of evaluation of an electric response of the PMSM 1 to the measuring voltage. This evaluation was conducted by installing a program to PE-Expert 3 (an inverter MWINV-5R022 produced by Myway Plus corporation). The control cycle Ts was set to 0.1 ms. In the measuring voltage to be applied, the angular frequency ωₕ was set to 800π rad/s, the voltage amplitude vₕ to 150 V, and the voltage applying time t to 10 ms. The evaluated motor, which has saliency, is of the type as shown in Table 1.

TABLE 1

| | | |
|---|---|---|
| Coil Resistance R₁ | 1.132 | Ω |
| Rated Power | 750 | W |
| Inductance L_{d} | 12.4 | mH |
| Inductance L_{q} | 15.6 | mH |
| Rated Current | 3.3 | Arms |
| Rated Revolution Number | 1920 | min⁻¹ |
| Rated Torque | 3.73 | Nm |
| Magnetic Flux Φ | 0.254 | Vs/rad |

| | |
|---|---|
| Pole Pair Number Nₚ | 3 |
| Maker | Yaskawa Electric Corp. |

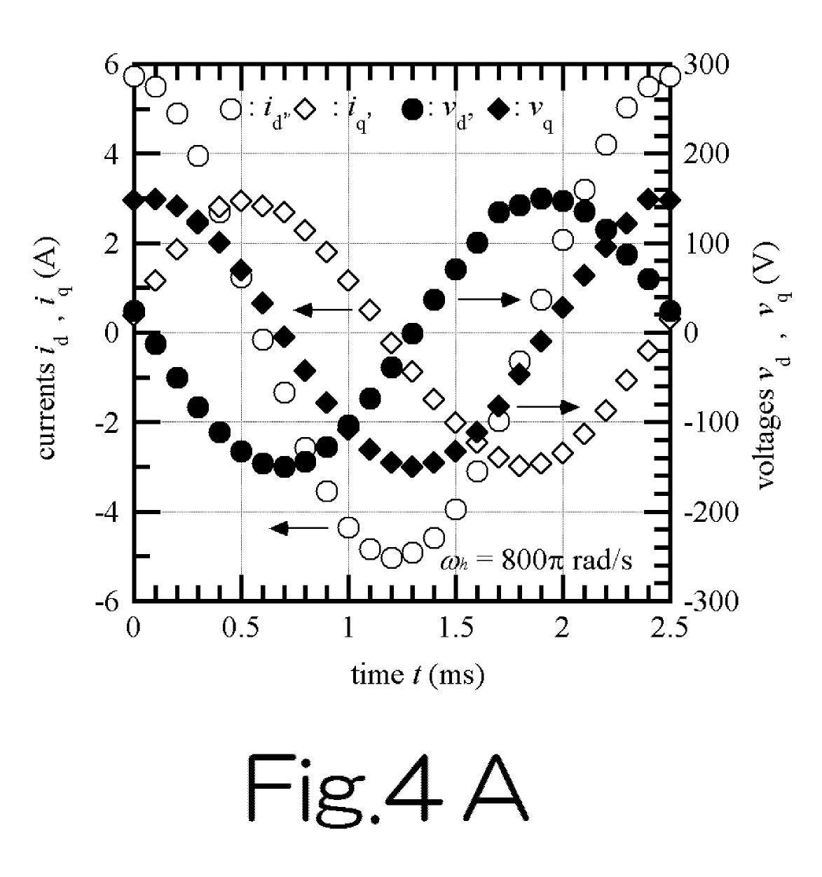

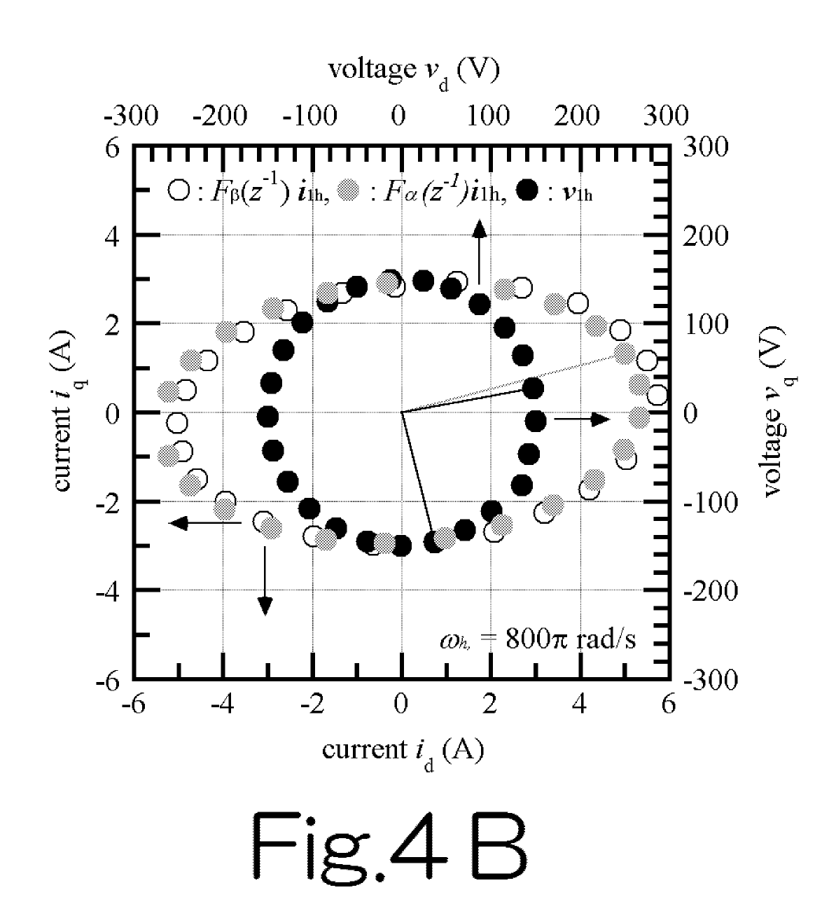

FIGS. 4A and 4B are views illustrating the evaluation results. FIG. 4A illustrates the response current i^{B}₁ₕ when the measuring voltage v^{B}₁ₕ is applied to the PMSM 1. In FIG. 4A, white circles and white rhombuses indicate a d-axis current i_{d} and a q-axis current i_{q}, respectively. In FIG. 4A, the black circles and the black rhombuses indicate a d-axis voltage V_{d} and a q-axis voltage V_{q}, respectively. FIG. 4B illustrates the trajectories of the response current i^{B}₁ₕ and the measuring voltage v^{B}₁ₕ in a d-q fixed coordinate system. In FIG. 4B, the white circles, the gray circles and the black circles indicate the outputs F_{β}(z⁻¹)i^{B}₁ₕ and F_{α}(z⁻¹)i^{B}₁ₕ of the mapping filters and the measuring voltage v^{B}₁ₕ, respectively. In FIG. 4B, the solid lines indicate the positional relationship of the respective vectors at a certain control cycle.

From the above result, it can be noted that the response current i^{B}₁ₕ generated by the application of the perfectly-circular measuring voltage v^{B}₁ₕ draws an elliptical trajectory. This is because the ratio of the minor axis to the major axis of the ellipse drawn by the response current is equal to the inductance ratio L_{d}:L_{q}, as shown in Shinji Shinnaka, “Vector Control Technology of Permanent Magnet Synchronous Motor, Second Volume (Essence of Sensorless Drive Control)”, Dempa Publications Inc., December 2008. In FIG. 4B, the center of the elliptical trajectory of the response current i^{B}₁ₕ is slightly shifted in the direction of i_{d}>0. This is because, when i_{d}>0, as compared with a case where i_{d}<0, the inductance is reduced due to the influence of magnetic saturation. From the output results F_{α}(z⁻¹)i^{B}₁ₕ and F_{β}(z⁻¹)i^{B}₁ₕ of the mapping filters, it is confirmed that the present filter advances the phase of the response current i^{B}₁ₕ by π/2 rad.

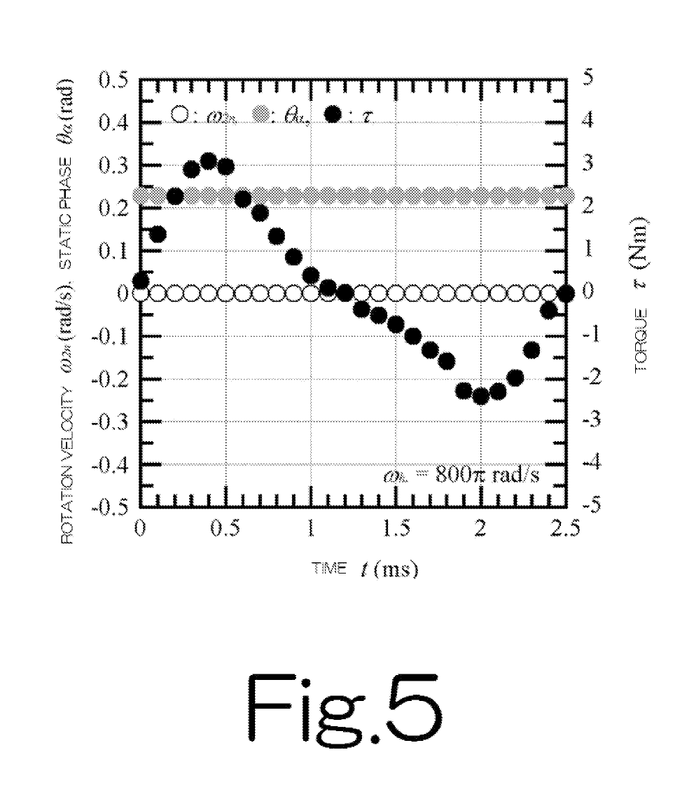

FIG. 5 illustrates the relationships between the generated torque τ, the rotor phase (static phase) θ_{α} and the rotor electric velocity ω₂ₙ at the time of application of the measuring voltage. The black circles indicate the torque τ, the gray circles indicate the static phase θ_{α}, and the white circles indicate the rotor electric velocity ω₂ₙ. The θ_{α} and the ω₂ₙ are the output result of an encoder (1024p/r). Since a torque sensor cannot follow the generated torque, the τ is calculated by mathematical formula 10 obtained by developing the torque generation formula of mathematical formula 1 in a d-q fixed coordinate system.

τ=Nₚi₁^{T}Jφ₁=Nₚ(2Lₘi_{d}+Φ)i_{q} Mathematical Formula 10

From this result, it can be noted that the rotor does not synchronize with the generated torque τ. Further, it is seen that θ_{α} becomes constant and ω₂ₙ becomes 0, thus satisfying the prerequisite ω₂ₙ=0 of mathematical formulae 6 and 9.

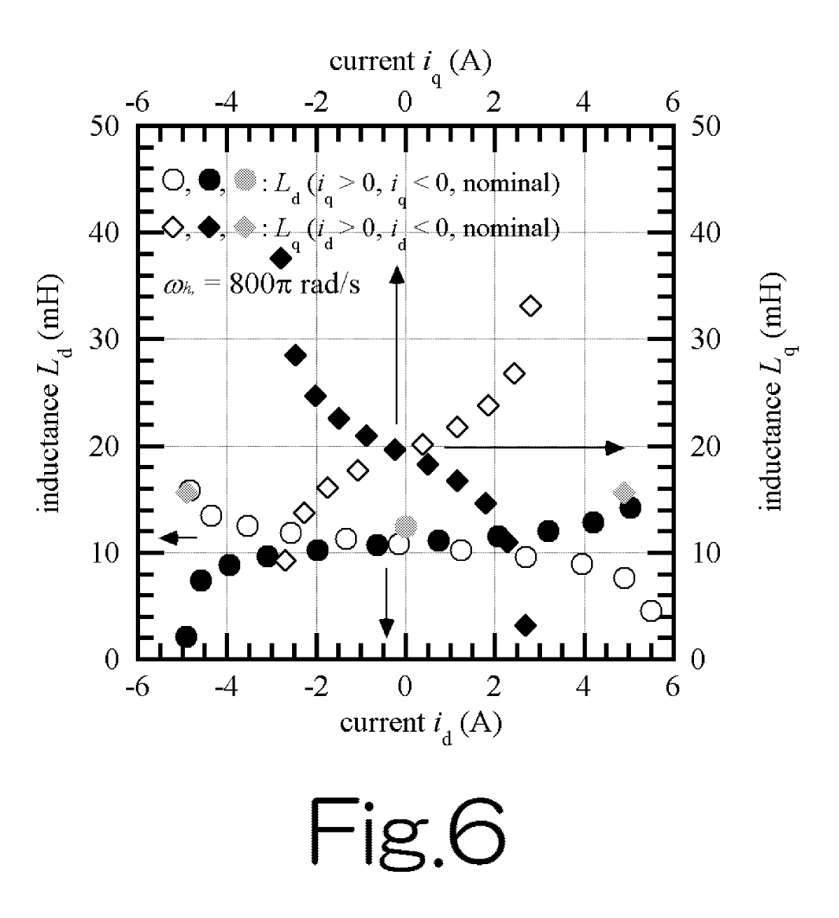

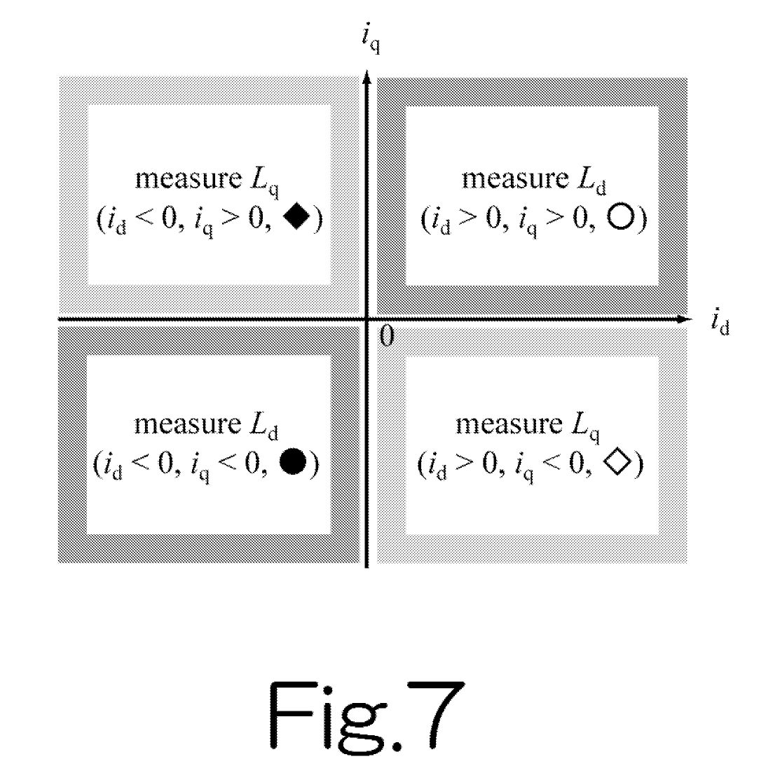

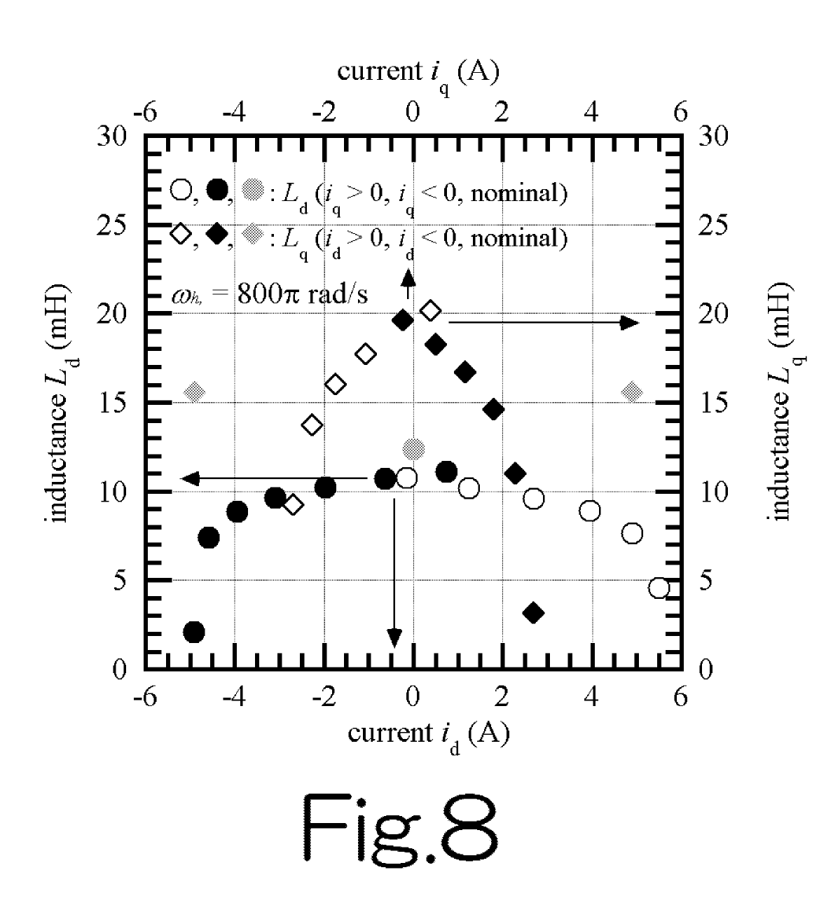

FIG. 6 is a view showing the measurement result of the inductance of a salient PMSM by the aforementioned measuring method. In FIG. 6, the gray circles and the gray rhombuses indicate d-axis and q-axis inductance nominal values written on a nameplate of the PMSM. In FIG. 6, the white circles and the black circles indicate the measurement result of the d-axis inductance L_{d} in case where i_{q}>0 and i_{q}<0, respectively. In FIG. 6, the white rhombuses and the black rhombuses indicate the measurement result of the q-axis inductance L_{q} in case where i_{d}>0 and i_{d}<0, respectively. From this result, it can be seen that, due to the combination of the polarities of i_{d} and i_{q}, there exist a region where the inductance increases along with the increase of the d-axis current or the q-axis current and a region where the inductance decreases along with the increase of the d-axis current or the q-axis current. In general, if the current increases, the inductance of the PMSM decreases due to the magnetic saturation. For that reason, in the test, as shown in FIG. 8 to be described later, a mask shown in FIG. 7 is applied to the measurement result, thereby ignoring the region where the inductance increases along with the increase of the current. The symbols shown in FIG. 7 are the same as those used in the subsequent test results.

FIG. 8 is a view illustrating the result obtained by applying the mask shown in FIG. 7 to the measurement result shown in FIG. 6. The symbols shown in FIG. 8 are the same as those shown in FIG. 6. This result reveals that a sharp decrease in the inductance appears near a region of i_{d}=±5 A and i_{q}=±3 A. This is because the si_{d} and the si_{q} of mathematical formula 9 become very small, thus generating zero division.

The error between the d-axis inductance L_{d} and the nominal value (gray circles) is about 10% or less, for example. Thus, if the manufacturing error and the measurement error of the nominal value are taken into account, the d-axis inductance L_{d} can be sufficiently measured by the present measuring method. However, if the influence of the S/N ratio of the si_{d} on the measurement accuracy is considered, the measurable range is a range of i_{d}=±4 A, namely a range of about ±80% of the response current, for example. In case of the q-axis inductance L_{q}, the maximum value of the response current is about 3 A which fails to reach 4.9 A required in the rated torque. For that reason, measurement cannot be conducted at a rated load point. As for the region equal to or less than a rated load current, the inductance can be measured in a range of i_{q}=±2 A, namely a range of ±70% of the response current. Even in this case, it is required to consider the S/N ratio of the si_{q}.

As for the measurement time, about 10 ms is required in measuring the inductance, for example. If the setup time for compiling and downloading a program is included, about 100 s is required in measuring the inductance. In a conventional LCR meter, a conventional impedance method, and a conventional magnetic flux linkage method, which include a setup operation, the measurement time is about 1 hr/PMSM, for example. Therefore, the present measuring method is capable of performing measurement at a speed of about 36 times greater than conventional methods.

As described above, in the case of the PMSM shown in Table 1, when the measurement range is about ±70% of the response current with respect to the applied measuring voltage, the inductance of the PMSM can be instantaneously measured by the present measuring method without requiring an external load device.

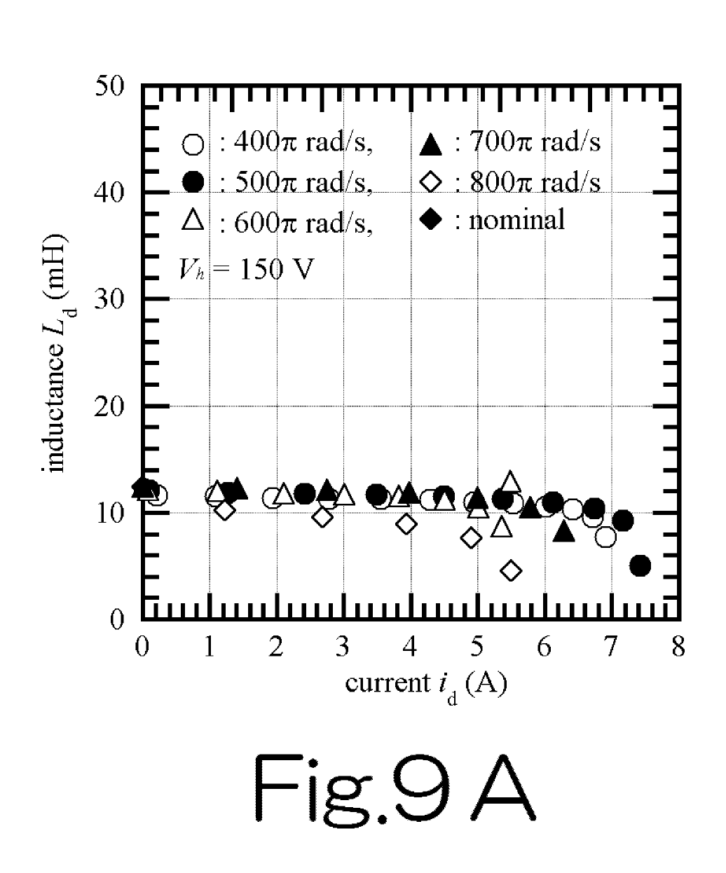

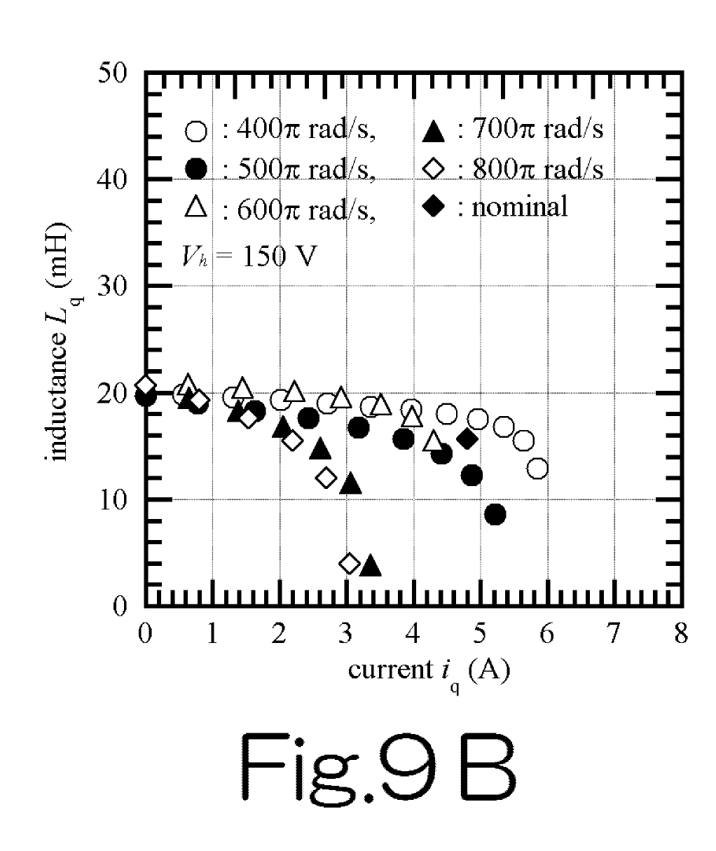

FIGS. 9A and 9B show the inductance measurement results in the cases where the amplitude Vₕ of the measuring voltage is set to 150 V and the angular frequency ωₕ thereof is changed within a range of 400π to 800π rad/s, for example. FIG. 9A shows the measurement result of the d-axis inductance L_{d} in the first quadrant (i_{d}>0 and i_{q}>0) shown in FIG. 7. FIG. 9B shows the measurement result of the q-axis inductance L_{q} in the second quadrant (i_{d}<0 and i_{q}>0) shown in FIG. 7. In FIGS. 9A and 9B, the white circles, the black circles, the white triangles, the black triangles and the white rhombuses indicate the respective measurement results in the case where the angular frequencies ωₕ are 400π, 500π, 600π, 700π and 800π rad/s. The black rhombuses indicate the nominal value.

The normalized angular frequencies Δθₕ of the mapping filters, the integer k and the degree n of the mapping filters are changed to the values shown in Table 2 depending on the angular frequencies ωₕ. From this result, it can be noted that the amplitude of the response current increases along with the decrease of the angular frequency. In all the angular frequencies, a sharp decrease of the inductance occurs in the region of about 80% or more of the maximum current, for example. Therefore, it is noted that the inductance can be measured in the range of about ±80% of the response current, for example. However, in the range of ωₕ≦500π rad/s, there appears a case where the rotary portion moves beyond a permissible range along with the application of the measuring voltage. In view of the foregoing, the tradeoff relationship between the angular frequency of the measuring voltage and the maximum response current needs to be grasped depending on a PMSM to be measured. In the case of the PMSM shown in Table 1, it is most preferable to conduct the measurement at ωₕ=600π rad/s.

TABLE 2

| ωₕ | Δθₕ = ωₕ^{Ts} | k | n |
|---|---|---|---|
| 400π rad/s | 0.04π rad | 1 | 25 |
| 500π rad/s | 0.05π rad | 1 | 20 |
| 600π rad/s | 0.06π rad | 3 | 50 |
| 700π rad/s | 0.07π rad | 7 | 100 |
| 800π rad/s | 0.08π rad | 2 | 25 |

Next, description will be made on the measurement result for a non-salient PMSM. The PMSM shown in Table 3 is used in this measurement.

TABLE 3

| | | |
|---|---|---|
| Coil Resistance R₁ | 4.32 | Ω |
| Rated Power | 387 | W |
| Inductance L_{d} | 60 | mH |
| Inductance L_{q} | 60 | mH |
| Rated Current | 1.9 | Arms |
| Rated Revolution Number | 1140 | min⁻¹ |
| Rated Torque | 3.24 | Nm |
| Magnetic Flux Φ | 0.262 | Vs/rad |

| | |
|---|---|
| Pole pair number Nₚ | 4 |
| Maker | NIDEC TECHNO MOTOR CORP. |

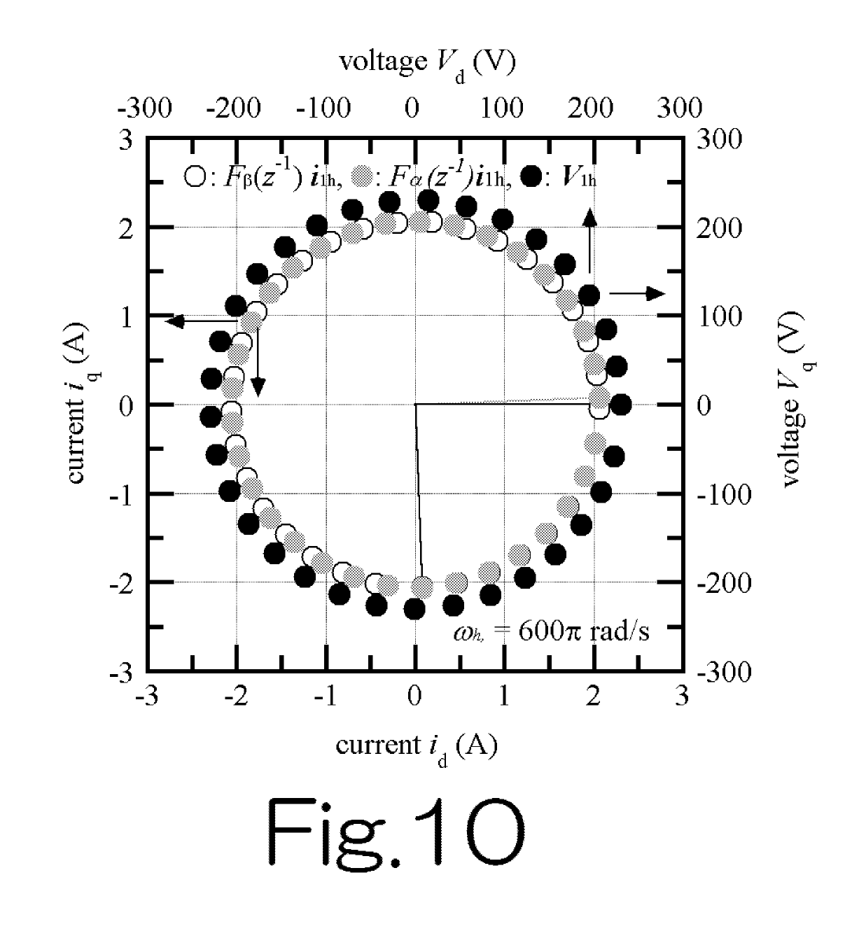

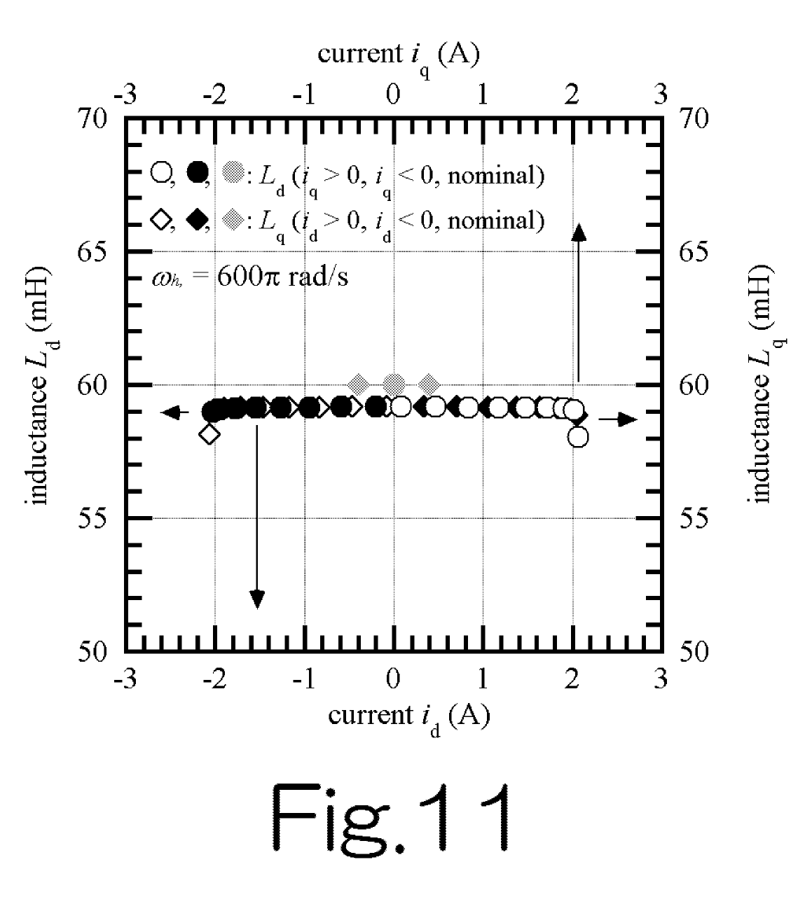

FIG. 10 shows the electric response of the PMSM to the measuring voltage. In FIG. 10, the white circles, the gray circles and the black circles indicate the outputs F_{β}(z⁻¹)i^{B}₁ₕ and F_{α}(z⁻¹)i^{B}₁ₕ of the mapping filters and the measuring voltage v^{B}₁ₕ, respectively. In FIG. 10, the solid lines indicate the positional relationships of the respective vectors at a certain control cycle. FIG. 11 shows the measurement result of the inductance. In FIG. 11, the gray circles and the gray rhombuses indicate d-axis and q-axis inductance nominal values, respectively. In FIG. 11, the white circles and the black circles indicate the measurement result of the d-axis inductance L_{d} in the cases where i_{q}>0 and i_{q}<0, respectively. In FIG. 11, the white rhombuses and the black rhombuses indicate the measurement result of the q-axis inductance L_{q} in the cases where i_{d}>0 and i_{d}<0, respectively. The amplitude Vₕ of the measuring voltage is set to 230 V. The angular frequency ωₕ is set to 600π rad/s. The angular frequency ωₕ is selected as a value by which the measurement conditions are satisfied and at which the response current becomes the largest. The symbols shown in FIGS. 10 and 11 are the same as those shown in FIGS. 4B and 8.

From this result, it can be noted that a perfectly-circular response current is generated in response to a perfectly-circular measuring voltage. This is because the PMSM is non-salient and because L_{d} is equal to L_{q}. The result shown in FIG. 11 reveals that the inductance measurement values (L_{d}=59.2 mH and L_{q}=59.2 mH) measured by the present measuring method are substantially coincident with the nominal values (L_{d}=60 mH and L_{q}=60 mH). Accordingly, it can be noted that the measurement accuracy is high enough in the present measuring method. As in the measurement result shown in FIG. 8, a sharp decrease in the inductance appears near a region of i_{d}=±2.1 A and i_{q}=±2.1 A where the response current becomes the largest. That is to say, in the case of the PMSM shown in Table 3, measurement can be conducted with high enough accuracy if the measurement range is about ±90% of the response current. From the results shown in FIGS. 8 and 11, it can be said that, regardless of the saliency of the PMSM, the measurable range of the inductance is about ±80% of the response current, for example.

Next, description will be made on the measurement result for a PMSM having an extremely small inductance of 1 mH or less. The PMSM shown in Table 4 is used in this measurement.

TABLE 4

| | | |
|---|---|---|
| Coil Resistance R₁ | 37.25 | mΩ |
| Rated Power | 250 | W |
| Inductance L_{d} | 0.22 | mH |
| Inductance L_{q} | 0.28 | mH |
| Rated Current | 20 | Arms |
| Rated Revolution Number | 2700 | min⁻¹ |
| Rated Torque | 0.6 | Nm |
| Magnetic Flux Φ | 7.27 | Vs/rad |

| | |
|---|---|
| Pole pair number Nₚ | 5 |
| Maker | NIDEC CORP. |

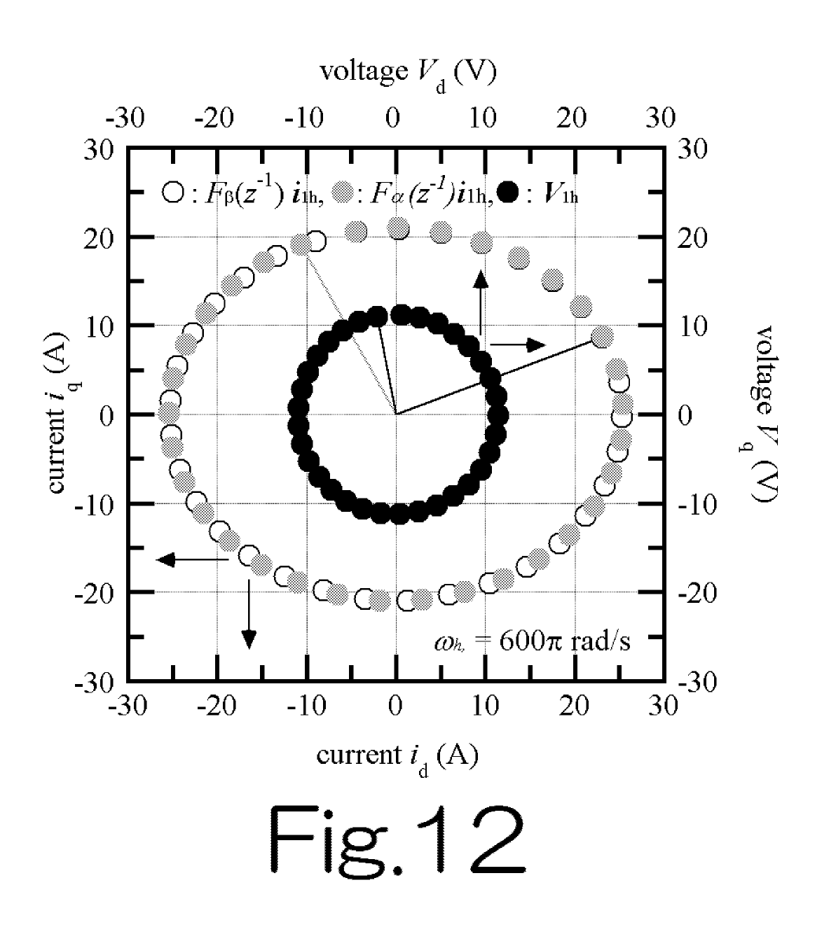

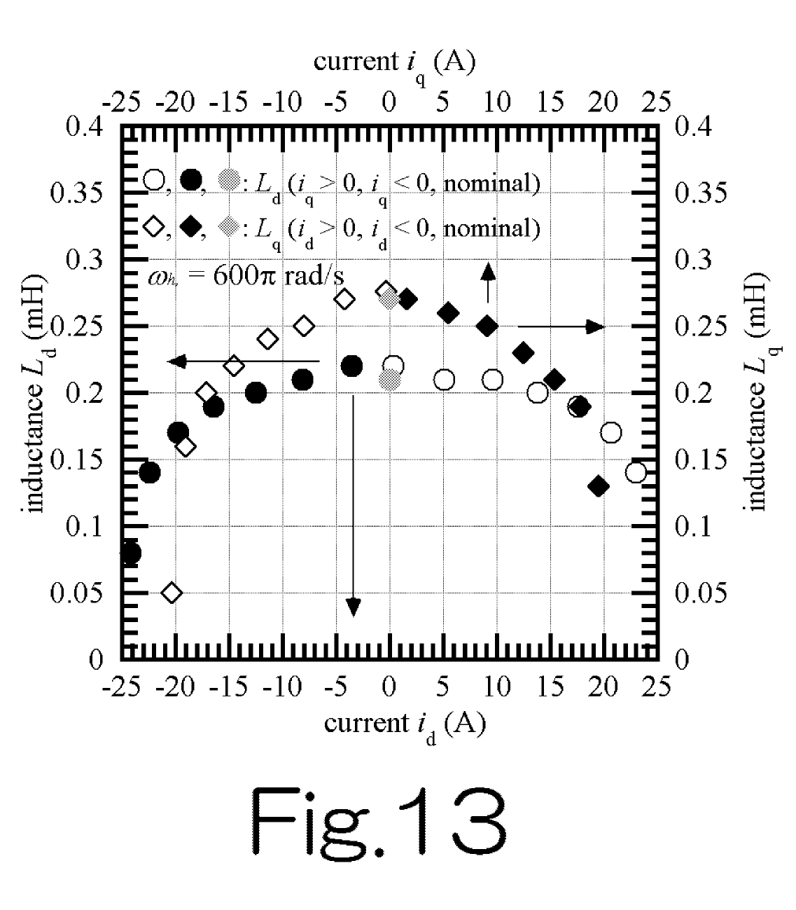

FIG. 12 shows the electric response of the PMSM to the measuring voltage. In FIG. 12, the white circles, the gray circles and the black circles indicate the outputs F_{β}(z⁻¹)i^{B}₁ₕ and F_{α}(z⁻¹)i^{B}₁ₕ of the mapping filters and the measuring voltage v^{B}₁ₕ, respectively. In FIG. 12, the solid lines indicate the positional relationships of the respective vectors at a certain control cycle. FIG. 13 shows the measurement result of the inductance. In FIG. 13, the gray circles and the gray rhombuses indicate d-axis and q-axis inductance nominal values, respectively. In FIG. 13, the white circles and the black circles indicate the measurement result of the d-axis inductance L_{d} in the cases where i_{q}>0 and i_{q}<0, respectively. In FIG. 13, the white rhombuses and the black rhombuses indicate the measurement result of the q-axis inductance L_{q} in the cases where i_{d}>0 and i_{d}<0, respectively. The amplitude Vₕ of the measuring voltage is set to 11 V. The angular frequency ωₕ is set to 600π rad/s. The angular frequency ωₕ is selected as a value by which the measurement conditions are satisfied and at which the response current becomes largest. The symbols shown in FIGS. 12 and 13 are the same as those shown in FIGS. 4B and 8.

As shown in FIG. 13, in the case of the d-axis inductance L_{d}, the measurement value for the nominal value 0.22 mH is 0.221 mH, for example. Therefore, in the d-axis inductance L_{d}, the error between the measurement value and the nominal value is as small as about 0.5%, for example. In the case of the q-axis inductance L_{q}, the measurement value for the nominal value 0.28 mH is 0.276 mH, for example. Therefore, in the q-axis inductance L_{q}, the error between the measurement value and the nominal value is as small as about 1.4%, for example. Considering the manufacturing error and the measuring error of the nominal value, it can be said that both the d-axis inductance L_{d} and the q-axis inductance L_{q} can be sufficiently measured by the present measuring method.

While not shown in the drawings, the measurement result using a magnetic flux linkage method was that L_{d}≈0.20 mH (i_{d}=7 to 10 A) and L_{q}≈0.24 mH (i_{q}=7 to 10 A). This means that the present measuring method has measurement performance at least equivalent to that of the conventional methods. In FIG. 13, as in the results shown in FIGS. 8 and 11, the inductance sharply decreases near a region of i_{d}=±25 A and i_{q}=±20 A. Therefore, the measurable range of the response current is about ±80% of the response current, for example. As described above, even for the PMSM having an extremely small inductance of 1 mH or less, the present measuring method has measurement characteristics as good as those of the magnetic flux linkage method. In addition, as for the regions other than the rated load point, the present measuring method can conduct measurement at one time.

In the present measuring method, depending on the motor parameters of the PMSM, there may be a case where it is impossible to generate the response current equal or substantially equal to the rated current. As shown in FIG. 4B, the response current draws an elliptical trajectory. Thus, there is a possibility that an unnecessarily large response current may flow in the salient PMSM. In respect of the amplitude of the measuring voltage, as shown in FIGS. 4B and 10, if the inductance of the PMSM is large, the amplitude Vₕ of the measuring voltage needs to be 100 V or more. As a result, the drive circuit of the PMSM becomes larger in size. As for the amplitude of the response current, in the case of the PMSM having a small inductance shown in FIG. 12, an over-current is generated when an excessive measuring voltage is applied to the PMSM. This may possibly cause damage to the inverter and the PMSM. In order to apply the present measuring method to different kinds of PMSMs, it is preferable to install a current controller that adjusts the measuring voltage depending on the motor parameters.

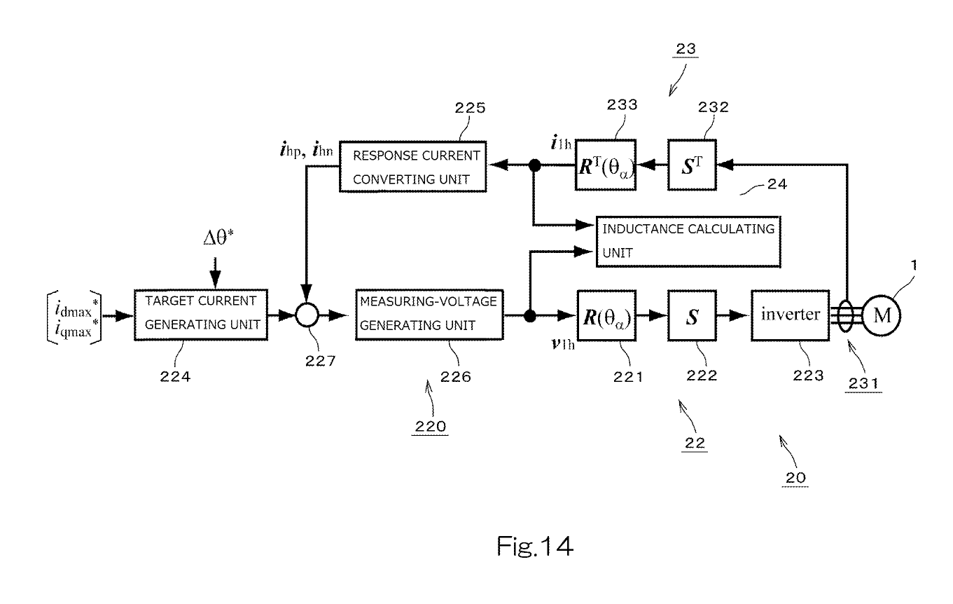

FIG. 14 is a view showing an improved measuring-voltage applying unit 22, a current measuring unit 23, and an inductance calculating unit 24. When installing the inductance measuring device 2 within the PMSM 1 as set forth above, it is preferred that the inductance measuring device 2 is configured and/or programmed as a part of a control unit 20 of the PMSM 1.

The current measuring unit 23 preferably includes a current detecting unit 231, a three-phase/two-phase converter 232 and a vector rotator 233. The measuring-voltage applying unit 22 preferably includes a vector rotator 221, a two-phase/three-phase converter 222, and an inverter 223. The improved measuring-voltage applying unit 22 further includes a target current generating unit 224, a response current converting unit 225, a measuring-voltage generating unit 226 and a subtracter 227. The response current converting unit 225, the measuring-voltage generating unit 226 and the subtracter 227 define a voltage control unit 220. The voltage control unit 220 is configured and/or programmed to control a measuring voltage based on a target current and a response current. Accordingly, it is possible to control a current value to fall within a suitable range.

The three-phase/two-phase converter 232 indicated by S^{BT} converts signals of three phases (u, v, and w phases) detected by the current detecting unit 231 to a α-β coordinate system. Using a static phase θ_{α}, the vector rotator 233 indicated by R^{BT} converts the signals of the α-β coordinate system to a d-q fixed coordinate system, namely a d-q coordinate system in which the rotary portion 12 is kept stationary. Using the static phase θ_{α}, the vector rotator 221 indicated by R^{B} converts the signals of the d-q fixed coordinate system to an α-β coordinate system. The two-phase/three-phase converter 222 indicated by S^{B} converts the signals of the α-β coordinate system to the signals of three phases (u, v and w phases), which are inputted to the inverter 223. The measuring-voltage applying unit 22 generates a measuring voltage using the static phase θ_{α}.

The inductance calculating unit 24 preferably corresponds to the digital filter 241 and the converter 242 shown in FIG. 3B.

In the case where the target current generating unit 224 and the voltage control unit 220 are not provided, a measuring voltage signal that draws a predetermined trajectory in the d-q fixed coordinate system is inputted to the vector rotator 221. In contrast, in the improved measuring-voltage applying unit 22, a measuring voltage is generated by the target current generating unit 224 and the voltage control unit 220, in which case an ideal trajectory of the response current is used as a command value.

The d-q fixed coordinate system belongs to the γ-δ general coordinate system. Therefore, the vector rotators 233 and 221 may perform conversion between the α-β coordinate system and the γ-δ general coordinate system. In this case, the inductance calculating unit 24 performs calculation in the γ-δ general coordinate system.

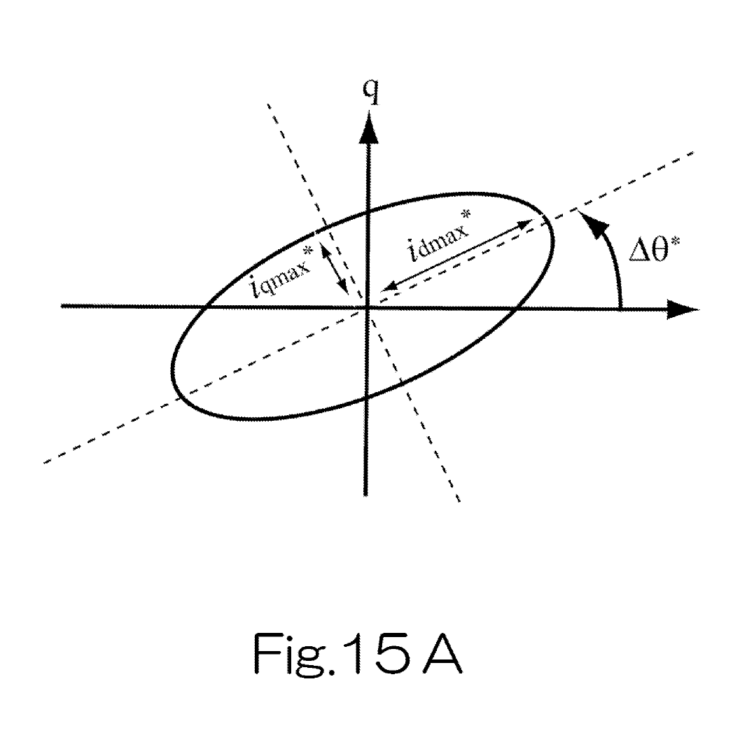

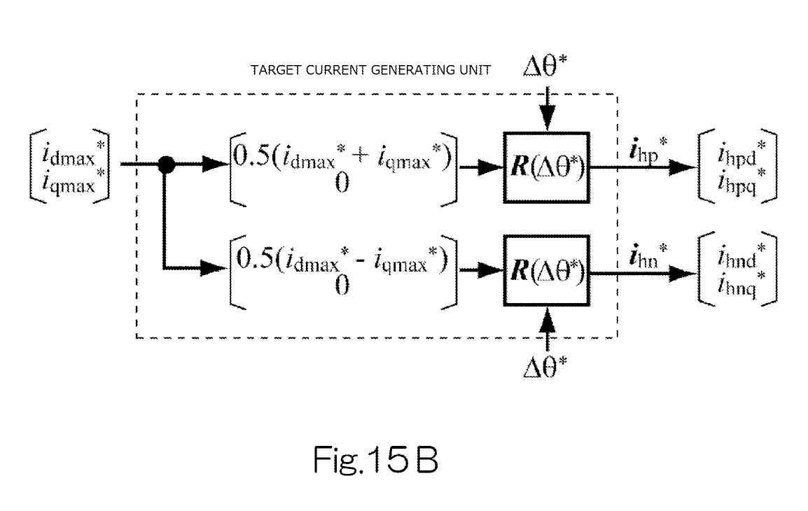

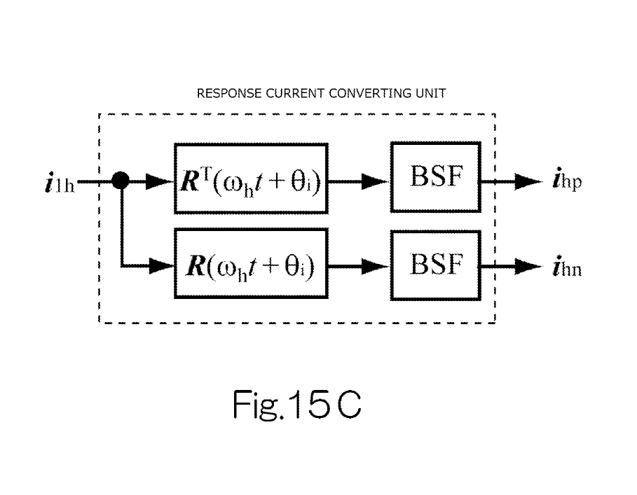

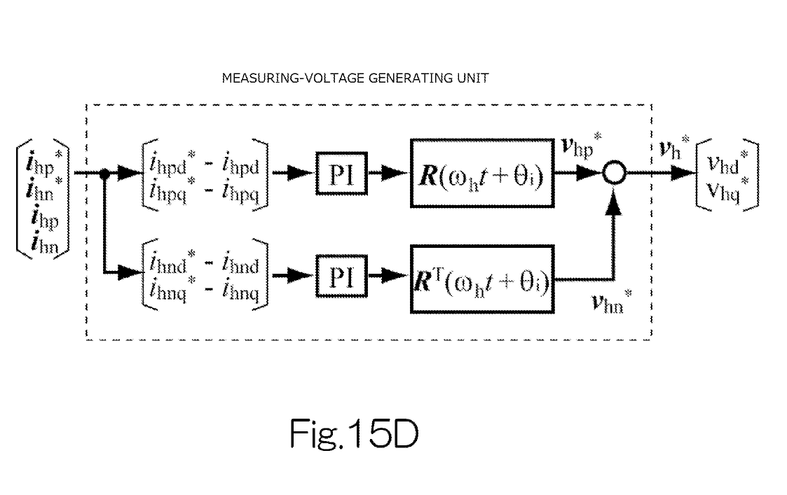

In general, in the d-q fixed coordinate system, the trajectory of a measuring voltage is a circle or an ellipse that surrounds an origin. In the d-q fixed coordinate system, the trajectory of a target current serving as a command value is also a circle or an ellipse that surrounds an origin. The coordinate system for showing the trajectory of the measuring voltage and the trajectory of the target current is not limited to the d-q fixed coordinate system. In a coordinate system for the expression of two phases, the trajectory of the measuring voltage is a circle or an ellipse that surrounds an origin, and the trajectory of the target current is also a circle or an ellipse that surrounds an origin. In the trajectory of the target current, as shown in FIG. 15A, the amplitude of the ellipse major axis of the target current is defined as i_{dmax}*, the amplitude of the ellipse minor axis thereof is defined as i_{qmax}*, and the phase of the ellipse major axis measured from the d-axis is defined as Δθ*. Subscripts d and q denote a d-axis component and a q-axis component, respectively.

FIG. 15B is a view showing the configuration of the target current generating unit 224. Using the vector rotator R^{B}(Δθ*), the target current generating unit 224 is configured to generate, as the target current, a positive phase command value i^{B}ₕₚ* and a negative phase command value i^{B}ₕₙ* from the i_{dmax}*, the i_{qmax}* and the Δθ*. FIG. 15C is a view showing the configuration of the response current converting unit 225. In the response current converting unit 225, the positive phase component of the response current i^{B}₁ₕ is converted to a DC component by the vector rotator R^{BT}. Then, the negative phase component is removed by a band stop filter (BSF) (having a center frequency of 2ωₕ and a bandwidth of ωₕ/3). Accordingly, a positive phase component i^{B}ₕₚ is obtained. Similarly, in the response current converting unit 225, the negative phase component of the response current i^{B}₁ₕ is converted to a DC component by the vector rotator R^{B}. Then, the positive phase component is removed by the same BSF. Accordingly, a negative phase component i^{B}ₕₙ is obtained. In FIG. 15C, for the convenience of calculation, an initial phase θᵢ is included in the rotated phase. However, as will be described later, the initial phase θᵢ is an extremely small value which is set to enhance the measuring accuracy. This holds true in FIG. 15D.

FIG. 15D is a view showing the configuration of the measuring-voltage generating unit 226. The positive phase component (i^{B}ₕₚ*−i^{B}ₕₚ) and the negative phase component (i^{B}ₕₙ*−i^{B}ₕₙ) obtained from the subtracter 227 are inputted to primary PI controllers, for each of a d-axis component and a q-axis component. The bandwidth of each of the primary PI controllers is, e.g., 3000 rad/s. Then, the outputs of the primary PI controllers are converted to command values v_{hpd}* and v_{hpq}* (i.e., v^{B}ₕₚ*) of positive phase components and command values v_{hnd}* and v_{hnq}* (i.e., v^{B}ₕₙ*) of negative phase components by the vector rotators R^{B}(ωₕt+θᵢ) and R^{BT}(ωₕt+θᵢ), respectively. A final measuring voltage v^{B}ₕ* is obtained by synthesizing these command values. In the aforementioned manner, the voltage control unit 220 controls the measuring voltage based on the target current and the response current.

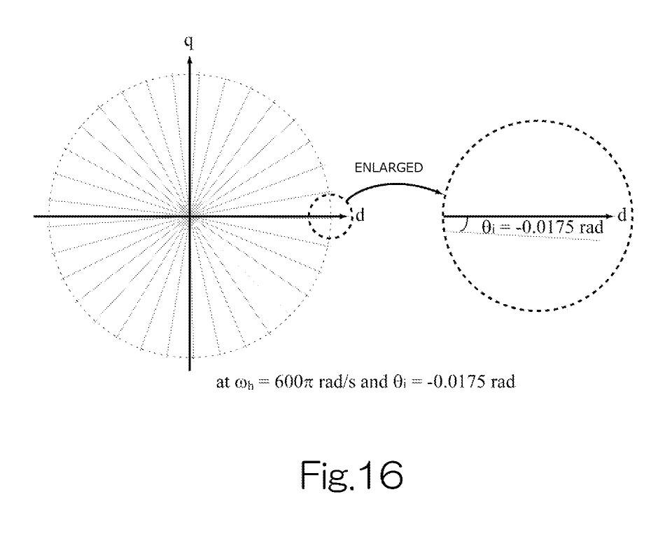

In the present preferred embodiment, as can be seen from the results shown in FIGS. 9A and 9B, the angular frequency ωₕ of the measuring voltage is preferably set to 600π rad/s, for example. Depending on the value of the angular frequency ωₕ, the coefficients of the mapping filters are set as shown in Table 2. With regard to the command value of the target current, the amplitude i_{dmax}* of the ellipse major axis preferably is set to 5.5 A, the amplitude i_{qmax}* of the ellipse minor axis preferably is set to 4.5 A, and the phase Δθ* of the ellipse major axis measured from the d-axis preferably is set to 0 rad, for example. As shown in FIG. 16, the initial phase θi is preferably set to −0.0175 rad, for example. Thus, the response current i^{B}₁ₕ at every moment of the control cycle is prevented from being positioned on the d-axis and the q-axis, thus preventing zero division of mathematical formula 9.

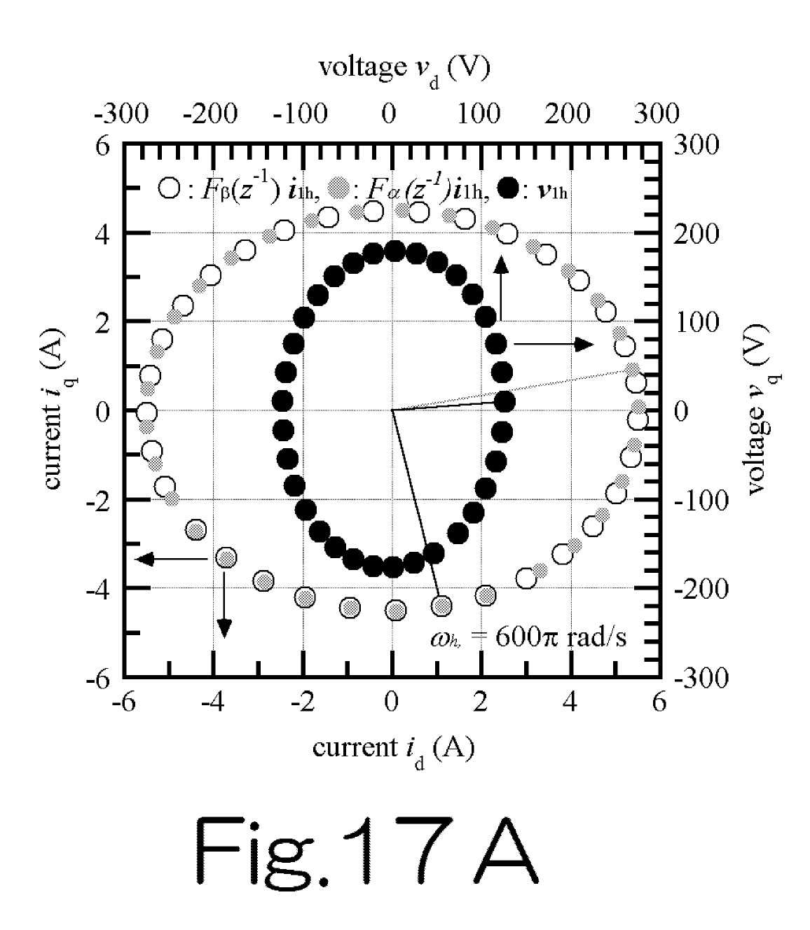

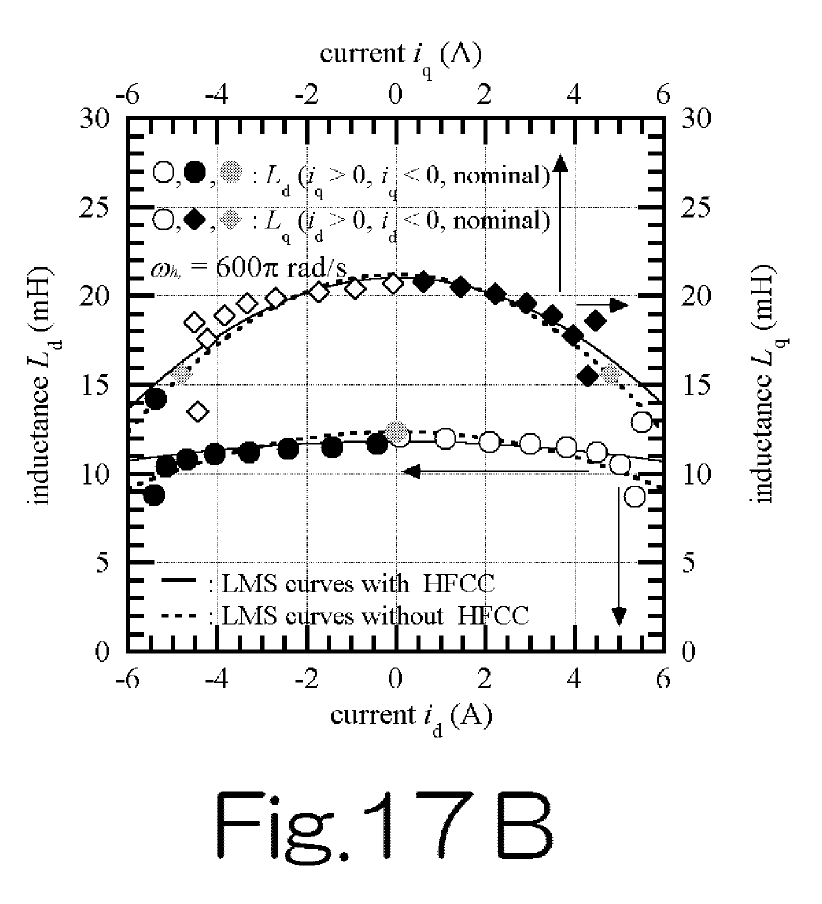

FIG. 17A is a view showing the relationship between the measuring voltage and the response current of the PMSM shown in Table 1, in the case of using the improved measuring-voltage applying unit 22. FIG. 17B shows an inductance measurement result. As compared with the result before improvement shown in FIG. 4B, it can be noted that the minor-axis/major-axis ratio of the response current attributable to saliency is corrected to obtain a response current close to a perfect circle which is suitable for measuring an inductance. In FIG. 17B, the d-axis inductance L_{d} and the q-axis inductance L_{q} can be function-approximated as indicated by solid lines. For example, a least square method may be used as the function approximation method. A formula of function approximation using the least square method is expressed in mathematical formula 11.

L_{d}=11.8−0.00337i_{d}−0.0309i_{d}²(mH)

L_{q}=21.0+0.0195i_{q}−0.202i_{q}²(mH) Mathematical Formula 11

In this regard, it has been confirmed that, even if the frequency ωₕ of the measuring voltage is set equal to 100π rad/s which is about ½ of the rated speed, a holding force is similarly applied to the rotary portion 12 and further that the inductance is capable of being measured at a measuring voltage amplitude vₕ≈10V. At this time, the response current at the same angular frequency has a maximum value which is four times as large as the rated current. Even in this case, it is possible to measure the inductance without causing damage to the PMSM 1. As described above, in one example of the present measuring method, the frequency of the measuring voltage is set to be within a range of about 50% to about 400% of the rated speed, for example, and the improve measuring-voltage applying unit 22 is used. Accordingly, the inductance is capable of being measured at a minimum voltage required in the measurement without depending on the motor parameters. Moreover, in one example of the present measuring method, it is possible to measure the inductance over a wide range where the maximum values of the d-axis current and the q-axis current become larger than the rated values.

Table 5 shows a comparison result of the performances of the present measuring method and the conventional methods. The time required in measuring the current values of 17 points which can be measured at one time in the present measuring method as shown in FIG. 17B is used as the measurement time of the conventional methods. The present measuring method is quite superior in performance to the conventional methods over a variety of aspects including the measurement range of the response current, the measurement time, the range of the measured angular frequency, the presence or absence of an external load device, the necessity of a position sensor, the measurement accuracy, the reproducibility and the like.

TABLE 5

| | | | Magnetic | |
|---|---|---|---|---|
| | | | Flux | Present |
| | | Impedance | linkage | Measuring |
| | LCR Meter | Method | Method | Method |
| Current Range | ≈0 | 0 to 1 | 0 to 1 | 0 to 4.0 |
| (Rated Ratio) | | | | |
| Frequency Range | 0 to 1 | 0 to 1 | 0 to 1 | 0.5 to 4.1 |
| (Rated Ratio) | | | | |
| External system | Position | Load system | | Unnecessary |
| | Controller | Position Sensor | | |
| | | (e.g., Encoder) | | |
| Measurement | 10⁵ | 17 | 17 | 1 |
| Time | (100 s) | (170 ms) | (170 ms) | (10 ms) |
| Total Inspection | >30 | | | 1 (10 ms) |
| time | (e.g., 1 Hour/PMSM, including | | | |
| | the Setup Time) | | | |
| Temperature | Good | Good | Poor | Good |
| Dependency | | | | |

| | | | |
|---|---|---|---|
| Measurement | Impedance | Depending on | Depending on |
| Range | Z > 1 Ω | Current Sensor and | Current Sensor |
| | | Voltage Sensor | |
| Accuracy | ±20% | ±10% | ±5% |

According to the measuring method of the present preferred embodiment, it is possible to easily measure the inductance within a short period of time. The details are as follows.

(1) The present measuring method does not require an external load device and a position sensor.

(2) In the present measuring method, it is possible to perform an automatic total inspection in a mass-production process within a measurement time of about 10 ms and within a total inspection time of about 100 s, for example. It is also possible to enhance the reliability of the PMSM.

(3) In the present measuring method, the measurement is capable of being conducted within a short period of time. It is therefore possible to instantaneously measure an inductance within a range of 0 to 4 times of a rated load current without causing damage to a test motor.

(4) In the conventional trajectory-oriented vector control, the true value of an inductance is unclear, so that a precise axis shift cannot be realized, which results in the reduction of the efficiency. In contrast, the use of the present measuring method makes it possible to utilize an optimal inductance.

(5) The use of the present measuring method makes it possible to utilize an inductance suitable for an observer in a high-speed rotation region and to reduce a phase estimation error, thus enhancing the efficiency.

(6) According to the present measuring method, it is possible to enhance the urgent acceleration and deceleration performance in the position-sensorless vector control. During the urgent acceleration and deceleration operation of the PMSM, a torque exceeding a rated load is generated momentarily. Consequently, the inductance value becomes different from the nominal value. In the conventional control method that makes use of the nominal value, a phase estimation error is generated and, therefore, the efficiency of the PMSM is reduced. On the other hand, in the present measuring method, it is possible to measure an inductance within a range several times larger than a rated load current value. For that reason, it is possible to prevent a reduction in the efficiency of the PMSM.

(7) All the signals required in measuring an inductance can be found by using the outputs of a voltage sensor and a current sensor installed in a drive circuit. Thus, an inductance measuring function can be added to an existing control circuit with no additional cost.

Conventionally, in a trial manufacturing process, the inductance of the PMSM has been measured only in an extremely limited region near a rated load point. The inductance value thus measured is used as the nominal value of mass-produced goods. As a result, a deviation is generated between the nominal value and the true value of the inductance. Since the calculation for the control of the PMSM is performed using the deviated nominal value, not only the vector control characteristic but also other control characteristics are deteriorated. Further, in the control using only the nominal value, it is not possible to cope with the change in the inductance value caused by the over-time degradation of the PMSM.

In the present measuring method according to preferred embodiments of the present invention, an inductance is measured by applying a measuring voltage, with which a PMSM cannot be substantially synchronized, to the PMSM that is kept stationary. Accordingly, it is possible to perform the inductance measurement over a wide current region exceeding a rated load current. It is also possible to instantaneously and accurately perform the inductance measurement without causing damage to the PMSM.

The inductance measuring method and the inductance measuring device in accordance with the aforementioned preferred embodiments can be modified in many different forms.

If the trajectory of the measuring voltage is a circle on a d-q fixed coordinate system, it is possible to estimate a static phase θ_{α} from the ellipse major axis direction of the trajectory of the response current. In this case, the static phase θ_{α} is obtained after measurement of the response current. The measuring voltage may be applied to the stator 111 without using the static phase θ_{α}.

The calculation of the inductance and the control of the measuring voltage need not be necessarily performed on the d-q fixed coordinate system but may be performed on other two-phase coordinate systems such as a γ-δ general coordinate system and the like. In all the cases, the trajectories of the measuring voltage and the response current surround an origin, so that it is possible to rapidly acquire inductances corresponding to a plurality of current values (e.g., current values over one cycle).

In the aforementioned preferred embodiments of the present invention, the mapping filters are presented as one non-limiting example of the digital filter. Other digital filters may be used.

The aforementioned preferred embodiments are based on a premise that, during the measurement, the rotary portion 12 is kept stopped with respect to the stationary portion 11. However, when considering that the measuring voltage is applied to the stator 111, the term “stopped” during the measurement does not indicate a physical stoppage in the strict sense but indicates a state that can be regarded as a stoppage in terms of calculation. As long as the rotary portion 12 is kept stopped at an electric angle of less than 12 degrees, for example, even if the rotary portion 12 is not stopped in the strict sense, it is possible to conduct the measurement as in the conventional methods. It is preferred that the rotary portion 12 is allowed to make fine movement at an electric angle of less than 5 degrees, for example. In this case, even if a calculation error is taken into account, it is possible to measure an inductance more accurately than the conventional methods. In the description made above, the static phase θ_{α} denotes an average rotation position of the rotary portion 12.

The PMSM may be either an inner-rotor type motor or an outer-rotor type motor or may be other types of motors. The voltage equation expressed in mathematical formula 1 may be variously changed. For example, the voltage equation may be a formula that reflects magnetic saturation, inter-axial magnetic flux interference, and harmonic waves of an induced voltage.

The configurations of the preferred embodiments and modified examples described above may be properly combined unless a mutual conflict arises.

Preferred embodiments of the present invention can be used in measuring an inductance in PMSMs having different structures and uses.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1-15. (canceled)

16. A method for measuring an inductance of a permanent magnet synchronous motor, comprising the steps of:
(a) applying, to a stator of a stationary portion of the permanent magnet synchronous motor, a measuring voltage having an electric angular velocity at which a rotary portion is not rotated;
(b) in parallel with the step (a), measuring a response current flowing through the stator by using a static phase of the rotary portion that is kept stopped with respect to the stationary portion;
(c) determining a differential value of the response current by using a digital filter; and
(d) obtaining an inductance of the stator by inputting the response current and the differential value of the response current to a converter prepared in advance.

17. The method of claim 16, further comprising:
a step of acquiring the static phase of the rotary portion before the step (b).

18. The method of claim 16, wherein a d-axis current and a q-axis current are acquired as the response current, and a plurality of d-axis inductance values corresponding to a plurality of d-axis current values and a plurality of q-axis inductance values corresponding to a plurality of q-axis current values are acquired as the inductance.

19. The method of claim 18, wherein the d-axis current and the q-axis current have a maximum value larger than a rated value.

20. The method of claim 16, wherein the converter includes a function or a lookup table used in converting the response current and the differential value of the response current to the inductance.

21. The method of claim 16, wherein the converter includes a function:
$$[ \begin{matrix}{L}_{d} \\ {L}_{q}\end{matrix} ] = [ \begin{matrix}\frac{{v}_{d} - {R}_{1} {i}_{d}}{{si}_{d}} \\ \frac{{v}_{q} - {R}_{1} {i}_{q}}{{si}_{q}}\end{matrix} ]$$
where v_{d} is a d-axis voltage of the measuring voltage, v_{q} is a q-axis voltage of the measuring voltage, i_{d} is a d-axis current of the response current, i_{q} is a q-axis current of the response current, si_{d} is a differential value of the d-axis current, si_{q} is a differential value of the q-axis current, and R₁ is a coil resistance of the stator.

22. The method of claim 16, wherein in the step (a), the measuring voltage is generated by using the static phase of the rotary portion.

23. A device for measuring an inductance of a permanent magnet synchronous motor, comprising:
a measuring-voltage applicator configured to apply, to a stator of a stationary portion of the permanent magnet synchronous motor, a measuring voltage having an electric angular velocity at which a rotary portion is not rotated;
a current measurer configured to measure a response current flowing through the stator to which the measuring voltage is applied, by using a static phase of the rotary portion that is kept stopped with respect to the stationary portion;
a digital filter configured to find a differential value of the response current; and
a converter configured to convert the response current and the differential value of the response current to an inductance of the stator.

24. The device of claim 23, further comprising:
a static phase acquirer configured to acquire the static phase of the rotary portion.

25. The device of claim 23, wherein the converter includes a function or a table configured to be used to convert the response current and the differential value of the response current to the inductance.

26. The device of claim 23, wherein the measuring-voltage applying unit includes a target current generator configured to find a target current, and a voltage controller configured or programmed to control the measuring voltage based on the target current and the response current.

27. A permanent magnet synchronous motor, comprising:
a stationary portion provided with a stator;
a rotary portion provided with a permanent magnet; and
a controller including:
a measuring-voltage applicator configured to apply, to the stator, a measuring voltage having an electric angular velocity at which the rotary portion is not rotated;
a current measurer configured to measure a response current flowing through the stator to which the measuring voltage is applied, by using a static phase of the rotary portion that is kept stopped with respect to the stationary portion;
a digital filter configured to find a differential value of the response current; and
a converter configured to convert the response current and the differential value of the response current to an inductance of the stator.

28. The motor of claim 27, further comprising:
a static phase acquirer configured to acquire the static phase of the rotary portion.

29. The motor of claim 27, wherein the converter includes a function or a table configured to be used to convert the response current and the differential value of the response current to the inductance.

30. The motor of claim 27, wherein the measuring-voltage applicator includes a target current generator configured to find a target current, and a voltage control unit configured or programmed to control the measuring voltage based on the target current and the response current.
